(19) United States
(12) Patent Application Publication
(10) Pub. No.: US 2011/0306197 A1
(43) Pub. Date: Dec. 15, 2011

(54) Methods of Manufacturing Semiconductor Devices

(76) Inventors: Young-Hoo Kim, Hwaseong-si (KR); Bo-Un Yoon, Seoul (KR); Kun-Tack Lee, Suwon-si (KR); Dae-Hyuk Kang, Hwaseong-si (KR); Im-Soo Park, Seongnam-si (KR)

(21) Appl. No.: 13/156,729

(22) Filed: Jun. 9, 2011

(30) Foreign Application Priority Data
Jun. 15, 2010 (KR) 10-2010-0056517

(51) Int. Cl. H01L 21/3205

(52) U.S. Cl. 438/593; 257/E21.209

(57) ABSTRACT

Method of manufacturing semiconductor device are provided including forming an insulation layer having a pad on a substrate; forming an etch stop layer on the insulation layer and the pad; forming a mold structure having at least one mold layer on the etch stop layer; forming a first supporting layer on the mold structure; etching the first supporting layer and the mold structure to form a first opening exposing the etch stop layer; forming a spacer on a sidewall of the first opening; etching the etch stop layer using the spacer as an etching mask to form a second opening, different from the first opening, exposing a first portion of the pad having a first associated area; etching the etch stop layer using the spacer as an etching mask to form a third opening exposing a second portion of the pad having a second associated area, the second associated area being larger than the first associated area; and etching the mold structure to form a fourth opening having a width larger than a width of the third opening.

### CROSS-REFERENCE TO RELATED APPLICATIONS

This application claims priority under 35 USC §119(e) to Korean Patent Application No. 2010-56517, filed on Jun. 15, 2010 in the Korean Intellectual Property Office (KIPO), the contents of which are herein incorporated by reference in their entirety.

### FIELD

This present inventive concept relates to semiconductor devices and methods of manufacturing semiconductor devices and, more particularly, to semiconductor devices including capacitors having improved structural stability while reducing contact resistance between a pad and a lower electrode.

### BACKGROUND

Recently, the size of semiconductor memory devices has been reduced as the integration degree of semiconductor memory devices has increased. Thus, capacitors present in these highly integrated semiconductor memory device may have increased height whereas a lower portion of the capacitor may have a decreased critical dimension (CD). Accordingly, a lower electrode of the capacitor may not properly make contact with a plug or a pad formed on a semiconductor substrate. Furthermore, the contact resistance between the lower electrode and the pad may increase. In other words, contact failure between the lower electrode and the pad may occur and cause electrical characteristics of the semiconductor memory device to deteriorate. To settle these problems, an etch stop layer positioned on the pad may be etched to increase an exposed area of the lower electrode while providing a supporting layer for supporting the lower electrode. However, the etch stop layer and the supporting layer may be formed using substantially similar nitrides, such that the supporting layer may be inadvertently etched during the etch of the etch stop layer. Thus, the lower electrode may collapse or fall down and also adjacent lower electrodes may lean on one other. As a result, an exposed area of a pad contacting a lower electrode may be increased while reducing the likelihood that the supporting layer is etched in a process of etching an etch stop layer protecting the pad.

### SUMMARY

Some embodiments of the present inventive concept provide semiconductor devices that improve connection stability between a lower electrode and a pad by enlarging an opening exposing the lower electrode while effectively protecting a supporting member of a capacitor.

Further embodiments provide methods of manufacturing semiconductor devices that improve connection stability between a lower electrode and a pad by enlarging an opening for the lower electrode while effectively protecting a supporting member of a capacitor.

Some embodiments provide methods of manufacturing semiconductor devices including forming an insulation layer having a pad on a substrate. An etch stop layer may be formed on the insulation layer and the pad. A mold structure having at least one mold layer may be formed on the etch stop layer. A first supporting layer may be formed on the mold structure. The first supporting layer and the mold structure may be etched to form a first opening exposing the etch stop layer. A spacer may be formed on a sidewall of the first opening. The etch stop layer may be etched using the spacer as an etching mask to form a second opening exposing a portion of the pad with a first area. The etch stop layer may be etched using the spacer as an etching mask to form a third opening exposing a portion of the pad with a second area substantially larger than the first area. After removing the spacer, the mold structure may be etched to form a fourth opening having a width substantially larger than a width of the third opening.

In forming the mold structure according to some embodiments, a first mold layer may be formed on the etch stop layer. A second mold layer may be formed on the first mold layer. The first mold layer and the second mold layer may include substantially different oxides, respectively. The first spacer may include an oxide or an oxynitride. Each of the etch stop layer and the first supporting layer may include a nitride.

In some embodiments, a lower electrode may be formed on a sidewall of the fourth opening and the pad. A first supporting member for supporting the lower electrode may be formed from the first supporting layer by removing the mold structure. A dielectric layer may be formed on the lower electrode and the first supporting member. An upper electrode may be formed on the dielectric layer. The sidewall of the fourth opening may have a stepped structure and a sidewall of the lower electrode may also have a stepped structure.

In further embodiments, an upper mold structure may be formed on the first supporting layer. The first opening may be formed from the upper mold structure to the first mold layer

In forming the upper mold structure according to some embodiments, a third mold layer may be formed on the first supporting layer. The third mold layer may include an oxide substantially different from that of the first mold layer or that of the second mold layer. A second supporting layer may be formed on the third mold layer. A second supporting member for supporting the lower electrode may be formed from the second supporting layer by removing the third mold layer with the first and the second mold layers.

In some embodiments, a sidewall of the fourth opening may have a multi-stepped structure and a sidewall portion of the lower electrode may also have a multi-stepped structure.

According to some embodiments, there is provided a method of manufacturing a semiconductor device. In the method of manufacturing the semiconductor device, an insulation layer having a buried pad may be formed on a substrate. An etch stop layer may be formed on the insulation layer and the pad. A lower mold structure may be formed on the etch stop layer. A first supporting layer may be formed on the lower mold structure. An upper mold structure may be formed on the first supporting layer. The upper mold structure may be etched to form a first opening exposing the first supporting layer. A first spacer may be formed on a sidewall of the first opening. The first supporting layer and the upper mold structure may be etched using the first spacer as an etching mask to form a second opening exposing the etch stop layer. The etch stop layer may be etched in a direction substantially perpendicular to the substrate using the first spacer as an etching mask to form a third opening exposing the pad. The etch stop layer may be etched in a direction substantially parallel to the substrate using the first spacer as an etching mask to form a fourth opening enlarging an exposed area of the pad. The lower mold structure may be etched to form a fifth opening having a lower width larger than that of the fourth opening.

In some embodiments, a lower electrode may be formed on a sidewall of the fifth opening and the pad. A first supporting member for supporting the lower electrode may be formed from the first supporting layer by removing the upper mold structure and the lower mold structure. The first spacer may be removed.

In some embodiments, a second spacer may be formed on a sidewall of the second opening. The second spacer may be removed after forming the fourth opening. At least one of an upper sidewall and a lower sidewall of the fifth opening may have a stepped structure. Further, at least one of an upper sidewall and a lower sidewall portion of the lower electrode may have a stepped structure. A second supporting layer may be formed on the upper mold structure. A second supporting member for supporting the lower electrode may be formed from the second supporting layer while removing the upper and the lower mold structures.

According to some embodiments, there is provided a semiconductor device including an insulation layer on a substrate, a pad buried in the insulation layer, a lower electrode contacting the pad, at least one supporting member contacting with a sidewall of the lower electrode, a dielectric layer on the lower electrode and the supporting member, and an upper electrode on the dielectric layer. The lower electrode may have a lower area substantially equal to or substantially larger than an upper area of the pad.

In some embodiments, the at least one supporting member may include a first supporting member contacting a central sidewall of the lower electrode and a second supporting member contacting an upper sidewall of the lower electrode.

In some embodiments, at least one of an upper sidewall and a lower sidewall of the lower electrode may have a stepped structure.

According to Some embodiments, the lower electrode of a capacitor may be formed on the pad widely exposed by the opening after enlarging the opening for the lower electrode. Thus, contact resistance between the pad and the lower electrode may be reduced and connection stability of the lower electrode relative to the pad may be enhanced. Because the semiconductor device includes the capacitor and the pad, the semiconductor device may provide improved stability and electrical characteristics. Further, the lower electrode may be supported by at least one supporting member and the lower electrode may include the sidewall having at least one stepped portion, so that falling down, leaning or collapsing of the lower electrode may be effectively prevented even though the lower electrode may have a high aspect ratio. As a result, the semiconductor may ensure more enhanced structural stability and storage capacity.

### BRIEF DESCRIPTION OF THE DRAWINGS

Example embodiments will be more clearly understood from the following detailed description taken in conjunction with the accompanying drawings. FIGS. 1 to 19 represent non-limiting, example embodiments as described herein.

FIGS. 1A to 1I are cross-sections illustrating methods manufacturing semiconductor devices in accordance with some embodiments of the present inventive concept.

FIGS. 2A to 2F are cross-sections illustrating methods of manufacturing semiconductor devices in accordance with some embodiments of the present inventive concept.

FIGS. 3A to 3D are cross-sections illustrating methods of manufacturing semiconductor devices in accordance with some embodiments of the present inventive concept.

FIGS. 4A to 4G are cross-sections illustrating methods of manufacturing semiconductor devices in accordance with some embodiments of the present inventive concept.

FIGS. 5A to 5F are cross-sections illustrating methods of manufacturing semiconductor devices in accordance with some embodiments of the present inventive concept.

FIGS. 6A to 6E are cross-sections illustrating methods of manufacturing semiconductor devices in accordance with some embodiments of the present inventive concept.

FIGS. 7A to 7E are cross-sections illustrating methods of manufacturing semiconductor devices in accordance with some embodiments of the present inventive concept.

FIGS. 8A to 8E are cross-sections illustrating methods of manufacturing semiconductor devices in accordance with some embodiments of the present inventive concept.

FIGS. 9A to 9E are cross-sections illustrating method of manufacturing semiconductor devices in accordance with some embodiments of the present inventive concept.

### DETAILED DESCRIPTION

Various example embodiments will be described more fully hereinafter with reference to the accompanying drawings, in which some example embodiments are shown. The inventive concept may, however, be embodied in many different forms and should not be construed as limited to the example embodiments set fourth herein. Rather, these example embodiments are provided so that this description will be thorough and complete, and will fully convey the scope of the inventive concept to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, third, fourth etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

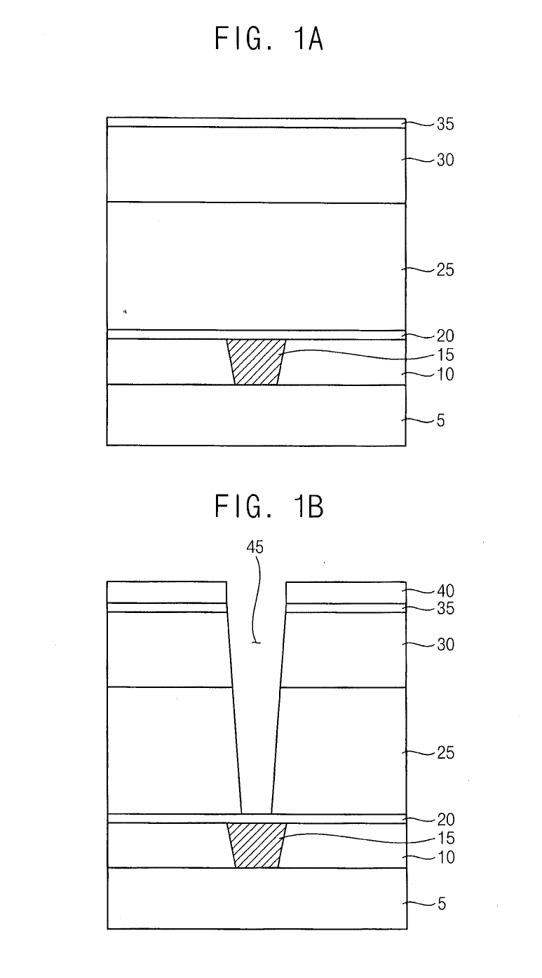

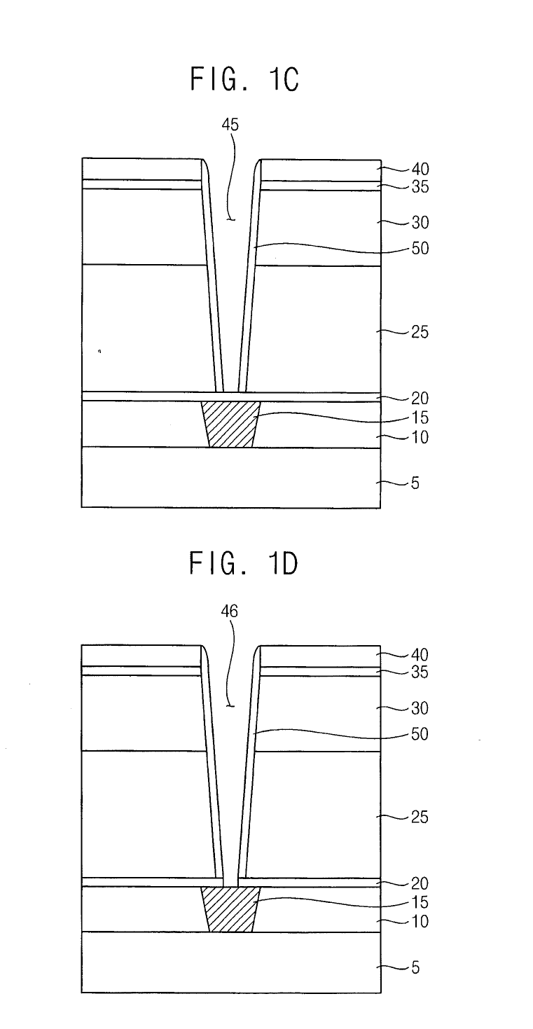

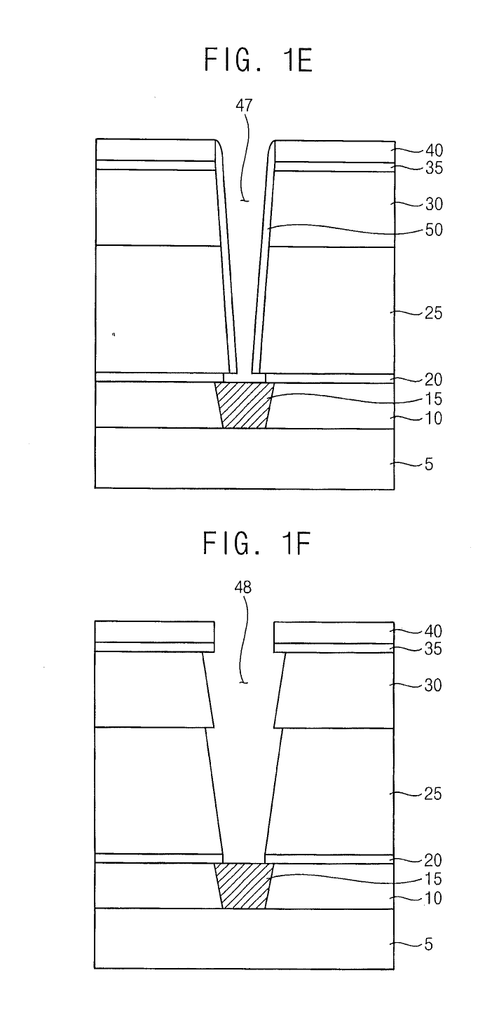

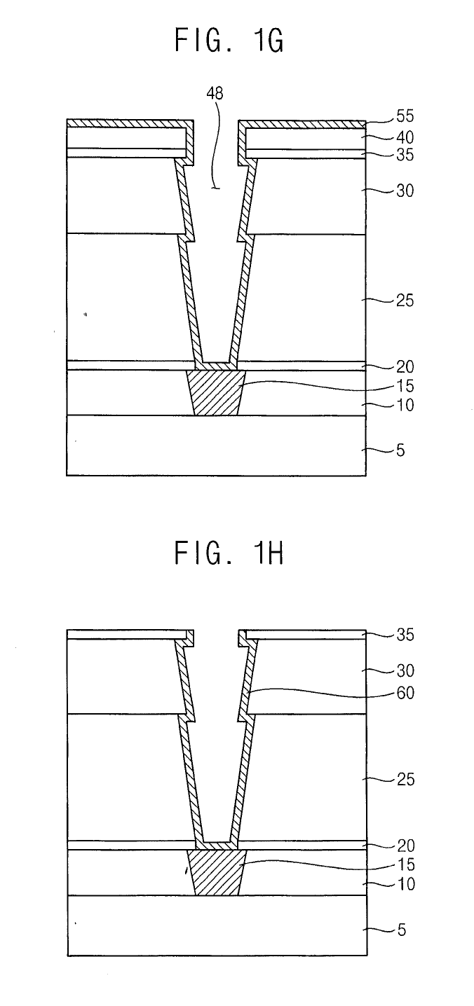

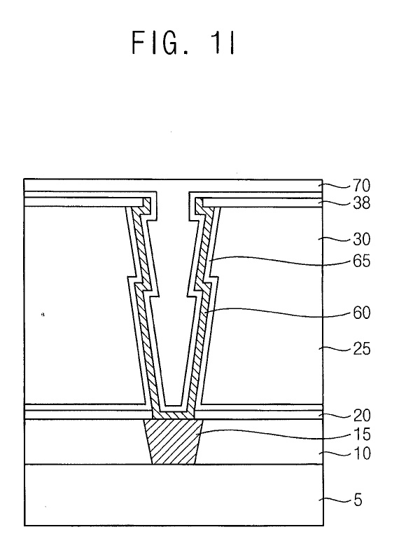

FIGS. 1A to 1I are cross-sections illustrating methods of manufacturing semiconductor devices in accordance with some embodiments of the present inventive concept. Referring to FIG. 1, an insulation layer 10 may be formed on a substrate 5 having a lower structure. The substrate 5 may include a semiconductor substrate or a substrate having a semiconductor layer. For example, the substrate 5 may include a silicon (Si) substrate, a germanium (Ge) substrate, a silicon-germanium (Si—Ge) substrate, a silicon-on-insulator (SOI) substrate, a germanium-on-insulator (GOI) substrate and the like.

In some embodiments, the lower structure may include various switching elements such as transistors, diodes, etc. Additionally, the lower structure may include contact regions, conductive patterns, insulation patterns, contacts, plugs, pads, etc., which are provided on the substrate 5.

The insulation layer 10 may be formed on the substrate 5 to sufficiently cover the lower structure. The insulation layer 10 may be formed using an oxide such as silicon oxide (SiOx). For example, the insulation layer 10 may include undoped silicate glass (USG), spin on glass (SOG), phosphor silicate glass (PSG), boro-phosphor silicate glass (BPSG), flowable oxide (FOX), TOnen SilaZane (TOSZ®), tetra ethyl ortho silicate (TEOS), plasma enhanced-TEOS (PE-TEOS), high density plasma-chemical vapor deposition (HDP-CVD) oxide, etc. These may be used alone or in a combination thereof. Additionally, the insulation layer 10 may be formed on the substrate 5 by a chemical vapor deposition (CVD) process, a plasma-enhanced chemical vapor deposition (PECVD) process, a spin coating process, an HDP-CVD process, etc.

In some embodiments, the insulation layer 10 may include at least one of an oxide film, a nitride film and an oxynitride film. In this case, the nitride film may include silicon nitride (SiNx) and the oxynitride film may include silicon oxynitride (SiOxNy), titanium oxynitride (TiOxNy), etc. At least a portion of the insulation layer 10 may correspond to an insulation interlayer for electrically insulating adjacent wirings.

After forming a contact hole (not illustrated) that exposes a predetermined portion of the substrate 5 by etching the insulation layer 10 through a photolithography process, a contact, a plug or a pad 15 may be formed on the substrate 5 to fill the contact hole. The plug or the pad 15 may include a conductive material. The pad 15 may be positioned on the predetermined portion of the substrate 5, for example, a contact region. The pad 15 may be formed using a metal and/or a metal compound. For example, the pad 15 may be formed using tungsten (W), titanium (Ti), aluminum (Al), copper (Cu), tantalum (Ta), tungsten nitride (WNx), titanium nitride (TiNx), aluminum nitride (AlNx), tantalum nitride (TaNx), titanium-aluminum nitride (TiAlxNy), etc. These may be used alone or in a combination thereof. The pad 15 may have a single layer structure which includes a metal film or a metal compound film Alternatively, the pad 15 may have a multilayer structure which includes at least one metal film and/or at least one metal compound film.

In some embodiments, after forming a conductive layer (not illustrated) on the insulation layer 10 to fill the contact hole, the pad 15 may be obtained by partially removing the conductive layer until the insulation layer 10 is exposed. In this case, the conductive layer may be formed by a sputtering process, a CVD process, an atomic layer deposition (ALD) process, a PECVD process, a vacuum evaporation process, etc. Additionally, the pad 15 may be formed in the contact hole by a chemical mechanical polishing (CMP) process and/or an etch-back process.

An etch stop layer 20 may be formed on the insulation layer 10 and the pad 15. The etch stop layer 20 may prevent and/or reduce the insulation layer 10 from being etched in subsequent etching processes to thereby protect the lower structure provided on the substrate 5. The etch stop layer 20 may be formed using a first nitride. For example, the first nitride may include silicon nitride. The etch stop layer 20 may be formed on the insulation layer 10 by a CVD process, a PECVD process, a low pressure chemical vapor deposition (LPCVD) process, etc.

In some example embodiments, after planarizing an upper portion of the insulation layer 10 by a CMP process and/or an etch-back process, the etch stop layer 20 may be formed on the insulation layer 10 having a level upper portion.

A first mold layer 25 may be formed on the etch stop layer 20. The first mold layer 25 may include a first oxide. For example, the first mold layer 25 may be formed using BPSG, PSG, USG, SOG, FOX, TOSZ®, TEOS, PE-TEOS, HDP-CVD oxide, etc. In an example embodiment, the first mold layer 25 may include BPSG. The first mold layer 25 may be formed on the etch stop layer 20 by a CVD process, a PECVD process, a spin coating process, an HDP-CVD process, etc.

In some embodiments, the first mold layer 25 may have a height of about 1,000 Å to about 2,000 Å from an upper portion of the etch stop layer 20. However, the thickness of the first mold layer 25 may be increased or reduced properly in accordance with a required capacitance of a capacitor in the semiconductor device.

A second mold layer 30 may be formed on the first mold layer 25. Thus, a mold structure including the first and the second mold layers 25 and 30 may be provided on the etch stop layer 20. The second mold layer 30 may be formed by depositing a second oxide on the first mold layer 25 through a CVD process, a PECVD process, a spin coating process, an HDP-CVD process, etc. For example, the second mold layer 30 may include the second oxide such as TEOS, PE-TEOS, BPSG, PSG, USG, SOG, FOX, TOSZ®, HDP-CVD oxide, etc. In some embodiments, the second mold layer 30 may include TEOS or PE-TEOS.

In some embodiments, the second oxide included in the second mold layer 30 may be substantially different from the first oxide included in the first mold layer 25. Therefore, the first mold layer 25 and the second mold layer 30 may have different etching rates with respect to a substantially identical etching gas or a substantially the same etching solution.

The second mold layer 30 may have a height of about 400 Å to about 1,000 Å measured from an upper portion of the first mold layer 25. Thus, a thickness ratio between the first mold layer 25 and the second mold layer 30 may be in a range of about 1:about 1 to about 1:about 5. As described above, a thickness of the second mold layer 30 may be increased or reduced properly in accordance with the required capacitance of the capacitor. The second mold layer 30 may be planarized by a CVD process and/or an etch-back process to ensure a level upper portion of the second mold layer 30.

A supporting layer 35 may be formed on the second mold layer 30 of the mold structure. The supporting layer 35 may be formed using a second nitride including silicon nitride. The second nitride in the supporting layer 35 may be substantially the same as or substantially similar to the first nitride in the etch stop layer 20. The supporting layer 35 may be formed on the second mold layer 30 by a CVD process, a PECVD process, a LPCVD process, etc. The supporting layer 35 may be changed into a supporting member 38 (see FIG. 1I) for supporting a lower electrode 60 (see FIG. 1H) of the capacitor in subsequent processes.

Referring to FIG. 1B, a mask pattern 40 for the lower electrode 60 may be formed on the supporting layer 35. The mask pattern 40 may be formed using a material having an etching selectivity relative to the supporting layer 35, the second mold layer 30 and/or the first mold layer 25. For example, the mask pattern 40 may be formed using polysilicon, amorphous silicon, amorphous carbon, etc. In an example embodiment, the mask pattern 40 may include polysilicon.

In example embodiments, the mask pattern 40 may have a height of about 4,000 Å to about 5,000 Å measured from an upper portion of the supporting layer 35. However, the height of the mask pattern 40 may be increased or reduced properly in accordance with process conditions of subsequent etching processes. The mask pattern 40 may expose a portion of the supporting layer 35 where the pad 15 is positioned.

A first opening 45 may be formed through the supporting layer 35, the second mold layer 30 and the first mold layer 25 by partially etching a portion of the supporting layer 35, the second mold layer 30 and the first mold layer 25 through a first etching process using the mask pattern 40 as an etching mask. That is, the first opening 45 may be formed from the supporting layer 35 to the first mold layer 25 by the first etching process. The first opening 45 may expose the etch stop layer 20 with a first area. Namely, the exposed portion of the etch stop layer 20 by the first opening 45 may have the first area. When the first mold layer 25 and the second mold layer 30 have relatively high heights, the first opening 45 may have a structure that includes a width reduced from an upper portion toward bottom portion thereof. Thus, the first opening 45 may have a sidewall inclined in a substantially perpendicular direction to the substrate 5 by a predetermined angle. Accordingly, the first area of the exposed portion of the etch stop layer 20 may be substantially the same as or substantially similar to a lower area of the first opening 45.

Referring to FIG. 1C, a spacer 50 may be formed on the sidewall of the first opening 45. The spacer 50 may be formed using a material having an etching selectivity with respect to the etch stop layer 20 and/or the supporting layer 35. For example, the spacer 50 may be formed using silicon oxide or silicon oxynitride.

In some embodiments, a spacer formation layer (not illustrated) may be formed on the sidewall of the first opening 45, the exposed portion of the etch stop layer 20 and the mask pattern 40, and then the spacer 50 may be formed by partially etching the spacer formation layer. The spacer formation layer may be conformally formed along a profile of the first opening 45. For example, the spacer formation layer may be formed by a CVD process, a PECVD process, an HDP-CVD process, an ALD process, etc.

Referring to FIG. 1D, with a second etching process using the spacer 50 and the mask pattern 40 as etching masks, the pad 15 may be exposed by etching the exposed portion of the etch stop layer 20 having the first area. When the etch stop layer 20 includes the first nitride, the etch stop layer 20 may be etched using an etching solution or an etching gas including phosphoric acid and/or sulfuric acid.

The pad 15 may be exposed with a first area through the second etching process, and the first opening 45 may be changed into a second opening 46 exposing the pad 15 with the first area. That is, the second opening 46 may be formed from the supporting layer 35 to the etch stop layer 20. In example embodiments, the first area of the exposed portion of the pad 15 may be substantially the same or similar to the first area of the exposed portion of the etch stop layer 20.

Referring to FIG. 1E, a portion of the etch stop layer 20 may be etched in a direction substantially parallel to the substrate 5 by a third etching process still using the spacer 50 as an etching mask. Thus, a third opening 47 exposing the etch stop layer 20 with a second area larger than the first area may be formed from the second opening 46. That is, a lower portion of the third opening 47 may be enlarged from a lower portion of the second opening 46. Thus, the pad 15 may be exposed with a second area. Namely, the second area of the exposed portion of the pad 15 by the third opening 47 may be relatively larger than the first area of the exposed portion of the pad 15 by the second opening 46.

In some embodiments, the etch stop layer 20 may be twice etched by two etching processes for etching the etch stop layer 20 along the direction substantially perpendicular to the substrate 5 and along the direction substantially parallel to the substrate 5. As a result, a width of the opening for forming the lower electrode 60 may be enlarged. That is, an exposed portion of the pad 15 may be enlarged by two etching process performed about the etch stop layer 20. Although a lower width of the third opening 47 is substantially smaller than a width of the pad 15 illustrated in FIG. 1E, process conditions of the third etching process may be properly controlled to obtain the third opening 47 having a lower width substantially the same as or substantially larger than an upper width of the pad 15.

Referring to FIG. 1F, after removing the spacer 50 from a sidewall of the third opening 47, a fourth opening 48 is formed by partially etching the first and the second mold layers 25 and 30. The fourth opening 48 may expose the pad 15 with a relatively large area. When the spacer 50 includes oxide, the spacer 50 may be etched using an etching solution or an etching gas including hydrogen fluoride (HF). For example, the spacer 50 may be removed using an LAL solution, etc.

In some embodiments, when the first and the second mold layers 25 and 30 include different oxides, a sidewall of the fourth opening 48 may have a stepped structure inclined relative to the substrate 5 by a predetermined angle. That is, when the first and the second mold layers 25 and 30 include different oxides, the sidewall of the fourth opening 48 may have a stepped portion because the first mold layer 25 and the second mold layer 30 are etched with different etching rates using the etching solution or the etching gas including HF. For example, the first mold layer 25 may be etched with a first etching rate substantially larger than a second etching rate of the second mold layer 30. Thus, a lower portion of the fourth opening 48 may have a width substantially the same as that of a lower portion of the third opening 47 whereas other portions of the fourth opening 48 may be enlarged to have widths substantially larger than those of other portions of the third opening 47. While forming the fourth opening 48 through the first and the second mold layer 25 and 30, the etch stop layer 20 and the supporting layer 35 may not be substantially etched because the etch stop layer 20 and the supporting layer 35 include nitrides.

Referring FIG. 1G, a lower electrode layer 55 may be formed on the exposed portion of the pad 15 having the second area, the sidewall of the fourth opening 48 and the mask pattern 40. The lower electrode layer 55 may include a metal and/or a metal compound. For example, the lower electrode layer 55 may be formed using titanium, titanium nitride, tantalum, tantalum nitride, aluminum, aluminum nitride, titanium-aluminum nitride, etc. These may be used alone or in a combination thereof. The lower electrode layer 55 may be formed by a sputtering process, a CVD process, an ALD process, a vacuum evaporation process, etc.

In some embodiments, the lower electrode layer 55 may be conformally formed along a profile of the fourth opening 48. When the sidewall of the fourth opening 48 has the stepped structure, a sidewall of the lower electrode layer 55 may also have a stepped structure or a stepped portion.

Referring to FIG. 1H, the lower electrode 60 may be formed on the sidewall of the fourth opening 48 and the pad 15 by partially removing the lower electrode layer 55 and the mask pattern 40 until the supporting layer 35 is exposed. The lower electrode 60 may be obtained by a CMP process and/or an etch-back process. As described above, the lower electrode 60 may have a stepped cylindrical structure in accordance with a shape of the fourth opening 48. That is, the lower electrode 60 may have a stable structure while ensuring a wide contact area with respect to the pad 15. Therefore, a contact resist between the lower electrode 60 and the pad 15 may be reduced, and the lower electrode 60 may not be collapsed, fallen down or leaned although the lower electrode 60 has a high aspect ratio.

Referring to FIG. 1I, the first mold layer 25 and the second mold layer 30 may be removed from the lower electrode, 60 and the supporting layer 35. For example, the first mold layer 25 and the second mold layer 30 may be removed by a lift off process. After removing the first mold layer 25 and the second mold layer 30, the supporting member 38 for supporting the lower electrode 60 may be obtained from the supporting layer 35. The supporting member 35 may prevent and/or reduce adjacent lower electrodes 60 from being leaned or being collapsed because the supporting member 38 makes contact with upper portions of the adjacent lower electrodes 60. As a result, a structural stability of the lower electrode 60 may be more improved.

A dielectric layer 65 may be formed on an inner sidewall and an outer sidewall of the lower electrode 60, the supporting member 38 and the etch stop layer 20. The dielectric layer 65 may include a nitride, an oxide and/or a metal oxide. For example, the dielectric layer 65 may be formed using silicon nitride, silicon oxide, tantalum oxide (TaOx), titanium oxide (TiOx), zirconium oxide (ZrOx), aluminum oxide (AlOx), etc. The dielectric layer 65 may have a single layer structure that includes a metal oxide film, a nitride film or an oxide film. Alternatively, the dielectric layer 65 may have a multilayer structure that includes at least one metal oxide film, at least one nitride film and/or at least one oxide film.

The capacitor having the lower electrode 60, the dielectric layer 65 and an upper electrode 70 may be formed over the substrate 5 by forming the upper electrode 70 on the dielectric layer 65. The upper electrode 70 may include a metal and/or a metal nitride. For example, the upper electrode 70 may be formed using titanium, titanium nitride, aluminum, aluminum nitride, tantalum, tantalum nitride, etc. These may be used alone or in a combination thereof. Although the upper electrode 70 may be formed as a plate structure illustrated in FIG. 1I, the upper electrode 70 may be conformally formed along profiles of the lower electrode 60 and the supporting member 38.

According to some embodiments, a contact area between a lower electrode and a pad or a plug may be increased and a contact resistance between the lower electrode and the pad may be reduced, so that a capacitor having the lower electrode may be stably connected to a predetermined region of a substrate with an improved electrical connection and enhanced structure stability. Therefore, a semiconductor device including the capacitor may also have improved electrical characteristics and enhanced structural stability.

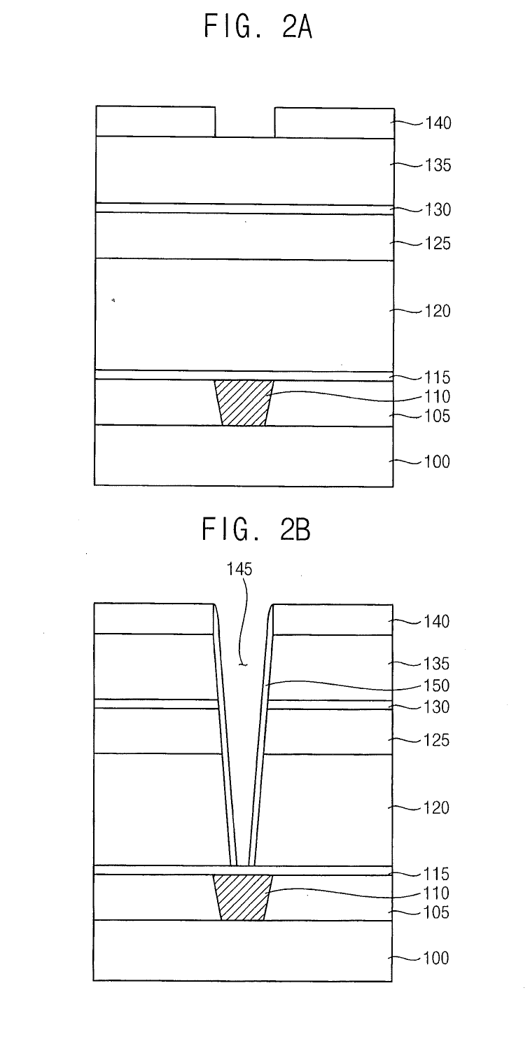

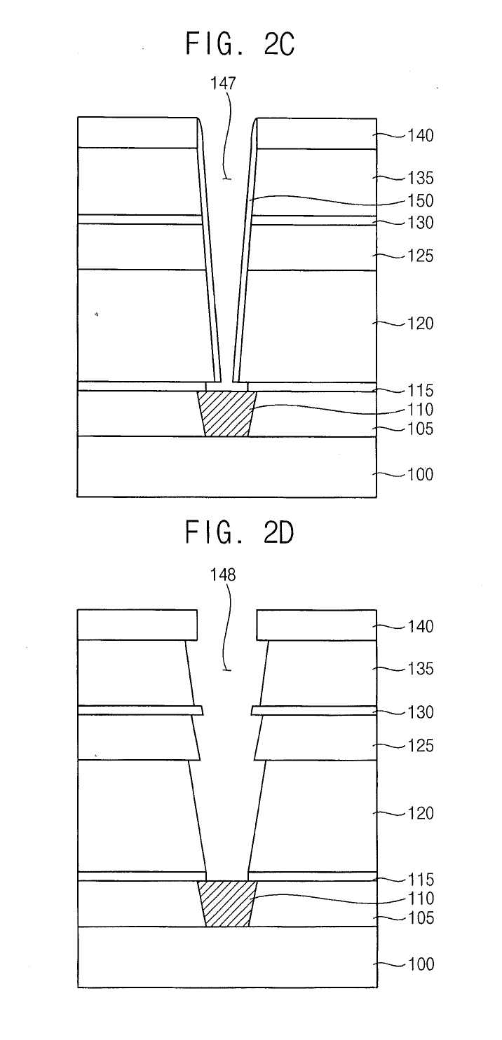

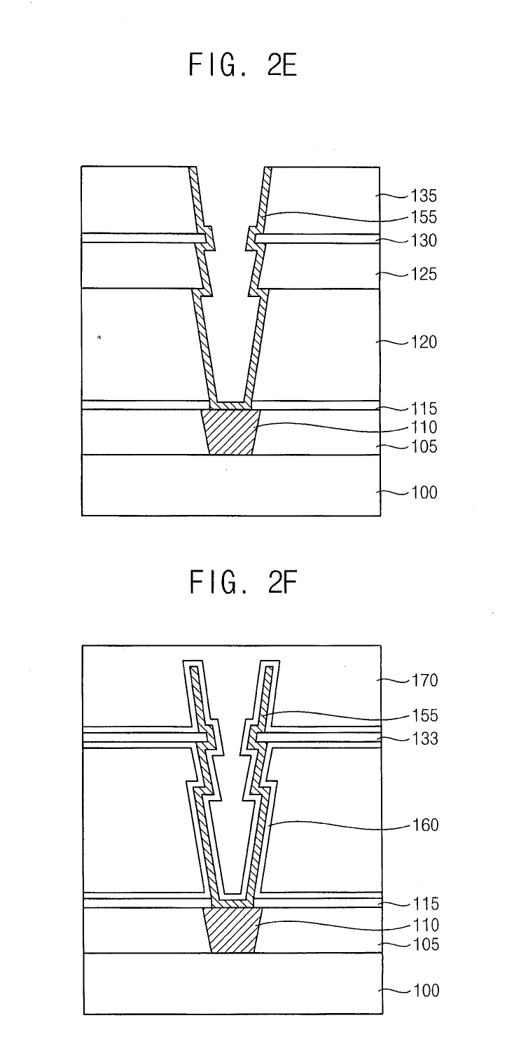

FIGS. 2A to 2F are cross-sections illustrating methods of manufacturing semiconductor devices in accordance with some embodiments of the present inventive concept. Referring to FIG. 2A, an insulation layer 105 may be formed on a substrate 100 and a pad 110 contacting a predetermined portion of the substrate 100 may be formed through the insulation layer 105. Here, an,upper portion of the pad 110 may be exposed by the insulation layer 105. The substrate 100 may include a semiconductor substrate or a substrate having a semiconductor layer thereon. The insulation layer 105 may include an oxide and the pad 110 may include a metal and/or a metal compound.

After forming an etch stop layer 115 on the insulation layer 105 and the pad 110, a first mold layer 120 may be formed on the etch stop layer 115. The etch stop layer 115 may be formed using a first nitride and the first mold layer 120 may be formed using a first oxide. For example, the first nitride may include silicon nitride and the first oxide may include silicon oxide having impurities such as BPSG, PSG and the like.

A second mold layer 125 may be formed on the first mold layer 120 to provide a lower mold structure having the first and the second mold layers 120 and 125 on the etch stop layer 115. The second mold layer 125 may be formed using a second oxide substantially different from the first oxide of the first mold layer 120. For example, the second oxide of the second mold layer 125 may include TEOS, PE-TEOS, etc.

A supporting layer 130 may be formed on the second mold layer 125 of the lower mold structure. The supporting layer 130 may include a second nitride. In this case, the second nitride of the supporting layer 130 may be substantially the same as or substantially similar to the first nitride of the etch stop layer 115.

An upper mold structure including a third mold layer 135 may be formed on the supporting layer 130. The third mold layer 135 may include a third oxide. For example, the third oxide of the third mold layer 135 may include HDP-CVD oxide. Thus, the supporting layer 130 may be positioned between the upper mold structure including the third mold layer 135 and the lower mold structure including the first and the second mold layers 120 and 125. In some embodiments, the third oxide of the third mold layer 135 may be substantially the same as or substantially similar to the second oxide of the second mold layer 125 and/or the first oxide of the first mold layer 120.

In some embodiments, the upper mold structure may include at least one mold layer. For example, the upper mold structure may include at least one additional mold layer formed on the third mold layer 135. Here, the additional mold layer may include an oxide substantially the same as or substantially similar to that of the first mold layer 120, the second mold layer 125 and/or the third mold layer 135. Alternatively, the additional mold layer may include an oxide substantially different from that of the first mold layer 120 and/or the second mold layer 125.

A mask pattern 140 may be formed on the third mold layer 135. The mask pattern 140 may be formed using a material having an etching selectivity relative to the supporting layer 130 and the first to the third mold layers 120, 125 and 135. For example, the mask pattern 140 may be formed using polysilicon, amorphous silicon, amorphous carbon, etc. The mask pattern 140 may have a height of about 4,000 Å to about 5,000 Å. The mask pattern 140 may expose a portion of the third mold layer 135 under which the pad 110 is positioned.

Referring to FIG. 2B, with a first etching process using the mask pattern 140 as an etching mask, the third mold layer 135, the supporting layer 130, the second mold layer 125 and the first mold layer 120 may be partially etched to form a first opening 145 that exposes a portion of the etch stop layer 115. Because the first opening 145 may be formed from the third mold layer 135 and the first mold layer 120, a lower portion of the first opening 145 may be considerably narrow. That is, the first opening 145 may have the lower portion having an area considerably smaller than that of an upper portion thereof. Thus, the etch stop layer 115 may be exposed with a relatively small first area.

A spacer 150 may be formed on a sidewall of the first opening 145. The spacer 150 may be formed using silicon oxide, silicon oxynitride, etc. The spacer 150 may be uniformly formed on the sidewall of the first opening 145. In this case, a lower portion of the spacer 150 may make contact with the etch stop layer 115. The spacer 150 may be obtained by anisotropically etching a spacer formation layer (not illustrated) after conformally forming the spacer formation layer along a profile of the first opening 145.

Referring to FIG. 2C, with a second etching process using the spacer 150 as the etching mask, a portion of the etch stop layer 115 exposed by the first opening 145 may be etched in a direction substantially perpendicular to the substrate 100. Hence, a second opening (not illustrated) exposing a portion of the pad 110 with a relatively small first area be formed from the third mold layer 135 to the etch stop layer 115. That is, the portion of the etch stop layer 115 having the first area may be etched to expose the portion of the pad 110 with first area.

A third etching process may be performed about the etch stop layer 115 still using the spacer 150 as an etching mask, so that a portion of the etch stop layer 115 exposed by the second opening may be etched in a direction substantially parallel to the substrate 100. Thus, a third opening 147 having an enlarged lower portion may be obtained from the second opening. Namely, the portion of the etch stop layer 115 may be etched to have a relatively large second area such that a portion of the pad 110 exposed by the third opening 147 may also have a relatively large second area. Although a width of a lower portion of the third opening 147 may be substantially smaller than a width of an upper portion of the pad 110 in FIG. 2C, the width of the lower portion of the third opening 147 may be substantially the same as or substantially larger than the width of the upper portion of the pad 110 by controlling process conditions of the third etching process.

Referring to FIG. 2D, after removing the spacer 150 from a sidewall of the third opening 147, a fourth opening 148 having an enlarged width may be formed from the third opening 147 by partially etching the first to the third mold layers 120, 125 and 135. That is, the first to the third mold layers 120, 125 and 135 may be partially etched with different etching rates to obtain the fourth opening 148 having a width substantially larger than that of the third opening 147.

In some embodiments, when the first to the third mold layers 120, 125 and 135 include substantially different oxides, the first to the third mold layers 120, 125 and 135 may be etched with substantially different etching rates using an etching solution such as an LAL solution. Thus, a sidewall of the fourth opening 148 may have a multi-stepped structure due to the difference of the etching rates of the first to the third mold layers 120, 125 and 135. For example, the sidewall of the fourth opening 148 may have a double-stepped structure, a triple-stepped structure, etc. That is, the fourth opening 148 may have two stepped portions, three stepped portions, etc. Here, the supporting layer 130 and the etch stop layer 115 may not be substantially etched.

As described above, when the sidewall of the fourth opening 148 has the multi-stepped structure, a sidewall of a lower electrode 155 (see FIG. 2E) formed in the fourth opening 148 may also have a multi-stepped structure. For example, the lower electrode 155 may have a double-stepped structure, a triple-stepped structure, etc. Therefore, a structural stability of the lower electrode 155 may be considerably enhanced while improving electrical connection between the pad 110 and the lower electrode 155.

Referring to FIG. 2E, a lower electrode layer (not illustrated) may be formed on the portion of the pad 110 exposed with the second area, the sidewall of the fourth opening 148 and the mask pattern 140. The lower electrode layer may be formed using a metal and/or a metal compound. The lower electrode layer may be conformally formed along a profile of the fourth opening 148 having the above-described structure.

The lower electrode 155 may be formed on the sidewall of the fourth opening 148 and the pad 110 by removing the mask pattern 140 and a portion of the lower electrode layer until the third mold layer 135 is exposed. As described above, the lower electrode 155 may have a multi-stepped cylindrical structure. As a result, a width of the lower electrode 155 may be enlarged, and also the structural stability of the lower electrode 155 may be improved.

Referring to FIG. 2F, after removing the upper mold structure including the third mold layer 135 and the lower mold structure including the first and the second mold layers 120 and 125 from the lower electrode 155, a supporting member 133 may be formed between adjacent lower electrodes 155 from the supporting layer 130. The upper mold structure and the lower mold structure may be etched using an etching solution including hydrogen fluoride, for example, an LAL solution.

A dielectric layer 160 may be conformally formed on the supporting member 133 and an inside and an outside of the lower electrode 155, and then an upper electrode 170 may be formed on the dielectric layer 160. Thus, a capacitor including the lower electrode 155, the upper electrode 170 and the dielectric layer 160 may be formed over the substrate 100. The upper electrode 170 may have a plate structure having a flat upper portion. Alternatively, the upper electrode 170 may be uniformly formed on dielectric layer 160.

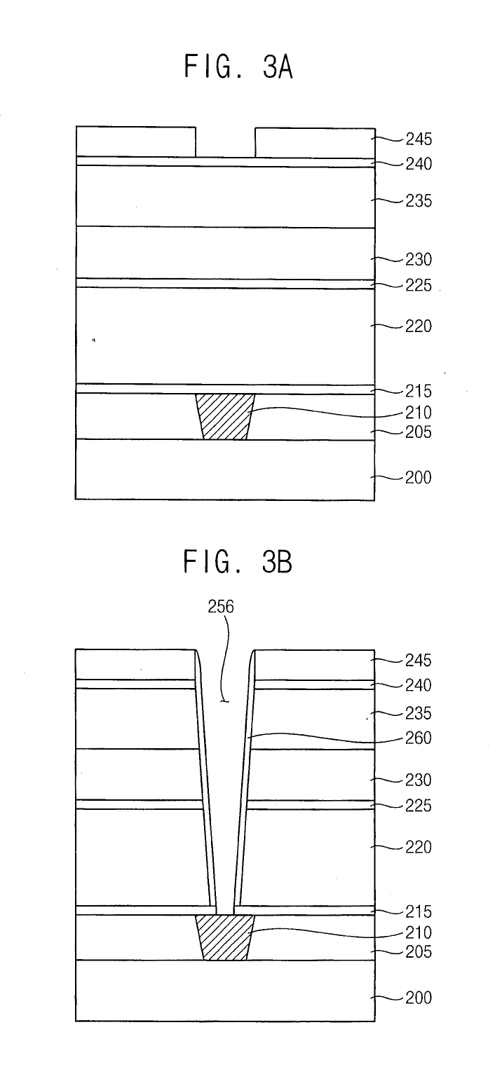

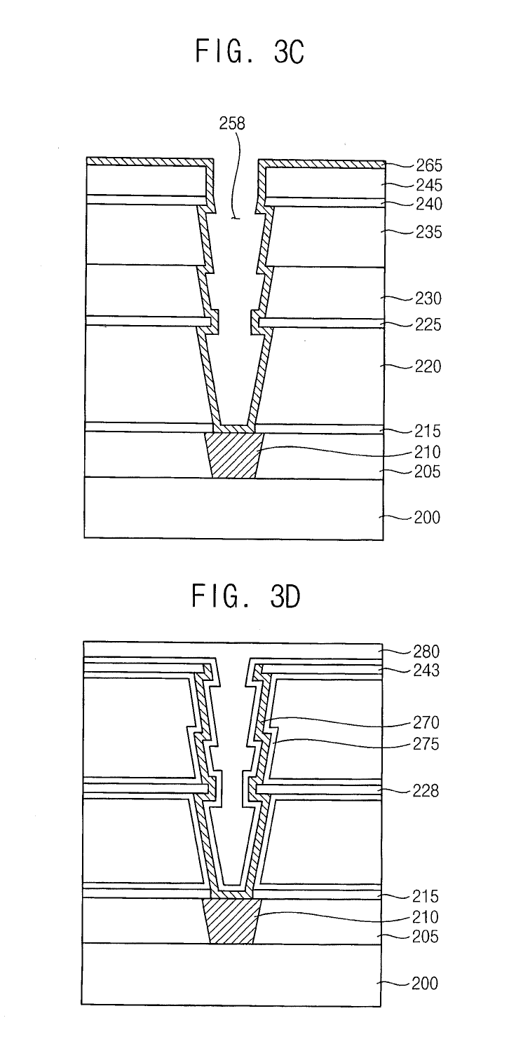

FIGS. 3A to 3D are cross-sections illustrating methods of manufacturing semiconductor devices in accordance with some embodiments of the present inventive concept. Referring to FIG. 3A, after forming an insulation layer 205 on the substrate 200 having a lower structure, a pad 210 may be formed on the substrate 200 through the insulation layer 205. The pad 210 may be buried in the insulation layer 205. The pad 210 may contact a predetermined portion of the substrate 200, for example, a contact region, a conductive region, a diffusion region, an impurity region, etc.

An etch stop layer 215 including nitride may be formed on the insulation layer 205 and the pad 210. The etch stop layer 215 may be formed using a first nitride, for example, silicon nitride. The etch stop layer 215 may have a relatively thin thickness.

A lower mold structure, a first supporting layer 225, an upper mold structure and a second supporting layer 240 may be successively formed on the etch stop layer 215. The lower mold structure may have a first mold layer 220 disposed on the etch stop layer 215, and the upper mold structure may have a second mold layer 230 and the third mold layer 235 formed between the first supporting layer 225 and the second supporting layer 240. In some example embodiments, the lower mold structure may include at least one additional mold layer disposed between the first mold layer 220 and the first supporting layer 225.

As illustrated in FIG. 3A, the first supporting layer 225 including a second nitride may be positioned between the first mold layer 220 of the lower mold structure and the second mold layer 230 of the upper mold structure. Additionally, the second supporting layer 240 including a third nitride may be located on the third mold layer 235 of the upper mold structure. In some embodiments, the first to the third mold layers 220, 230 and 235 may be formed using substantially different oxides, respectively. For example, the first to the third mold layers 220, 230 and 235 may be formed using BPSG, TEOS and HDP oxide, respectively.

A mask pattern 245 may be formed on the second supporting layer 240. The mask pattern 245 may be formed using a material having an etching selectivity with respect to the first supporting layer 225, the second supporting layer 240 and/or the first to the third mold structures 220, 230 and 235. The mask pattern 245 may expose a portion of the second supporting layer 240 under which the pad 210 is located.

Referring to FIG. 3B, the second supporting layer 240, the third mold layer 235, the second mold layer 230, the first supporting layer 225 and the first mold layer 220 may be partially etched by a first etching process using the mask pattern 245 as an etching mask. Thus, a first opening (not illustrated) exposing a portion of the etch stop layer 215 with a first area may be formed through the second supporting layer 240, the third mold layer 235, the second mold layer 230, the first supporting layer 225 and the first mold layer 220. That is, the first opening may be formed from the second supporting layer 240 to the first mold layer 220. The first area of the exposed portion of the etch stop layer 215 may be relatively small.

After forming a spacer 260 on a sidewall of the first opening, the exposed portion of the etch stop layer 215 may be etched by a second etching process using the spacer 260 and the mask pattern 245 as etching masks. As a result, a second opening 256 exposing a portion of the pad 210 may be formed from the second supporting layer 240 to the etch stop layer 215. The second opening 256 may expose a portion of the pad 210 with a first area substantially the same as or substantially similar to the first area of the portion of the etch stop layer 215. In the second etching process, the etch stop layer 215 may be partially etched along a direction substantially perpendicular relative to the substrate 200.

Referring to FIG. 3C, a third etching process may be performed about the etch stop layer 215 using the spacer 260 as an etching mask. The etch stop layer 215 may be partially etched along a direction substantially parallel to the substrate 200. Therefore, a third opening (not illustrated) may be formed to expose a portion of the pad 210 with a second area substantially larger than the first area. That is, the third opening may have an enlarged lower portion larger than that of the second opening 256. As described above, a width of the lower portion of the third opening may be substantially the same as or substantially similar to a width of the upper portion of the pad 210. Alternatively, the width of the lower portion of the third opening may be substantially larger than the width of the upper portion of the pad 210.

After removing the spacer 260 from the sidewall of the third opening using an etching solution or an etching gas including hydrogen fluoride, the first to the third mold layers 220, 230 and 235 may be partially etched to form a fourth opening 258 having an enlarged width from the third opening. When the first to the third mold layers 220, 230 and 235 include substantially different oxides, a sidewall of the fourth opening 258 may have a multi-stepped structure because of different etching rates of the first to the third mold layers 220, 230 and 235.

A lower electrode layer 265 may be formed on the sidewall of the fourth opening 258, the exposed portion of the pad 210 and the mask pattern 245. The lower electrode layer 265 may be formed conformally along a profile of the sidewall of the fourth opening 258. Thus, a sidewall of the lower electrode layer 265 may have a multi-stepped structure substantially the same as or substantially similar to that of the sidewall of the fourth opening 258.

Referring to FIG. 3D, an upper portion of the lower electrode layer 265 and the mask pattern 245 may be removed until the second supporting layer 240 is exposed, so that a lower electrode 270 may be formed on the exposed portion of the pad 210 and the sidewall of the fourth opening 258. The lower electrode 270 may have a multi-stepped cylindrical structure in accordance with the stepped structure of the fourth opening 258.

When the first to the third mold layers 220, 230 and 235 are removed, a first supporting member 228 and a second supporting member 243 may be obtained from the first supporting layer 225 and the second supporting layer 240, respectively. In example embodiments, the first supporting member may make contact a lower portion of the lower electrode 270 whereas the second supporting member 243 may make contact an upper portion of the lower electrode 270. That is, the first supporting member 228 may be positioned between lower portions of adjacent lower electrodes 270 and the second supporting member 243 may be located between upper portions of adjacent lower electrodes 270. When the lower electrode 270 is supported by the first and the second supporting members 228 and 243, a structural stability of the lower electrode 270 having a multi-stepped sidewall may be considerably improved. Therefore, a capacitor including the first and the second supporting members 228 and 243 may not be collapsed, fallen down or leaned even though the capacitor has a high aspect ratio.

A dielectric layer 275 may be formed on an inside and an outside of the lower electrode 270, the first supporting member 228 and the second supporting member 243. An upper electrode 280 may be formed on the dielectric layer 276. Thus, the capacitor may be obtained over the substrate 200. The capacitor may be electrically connected to the predetermined portion of the substrate 200 through the pad 210. The upper electrode 280 may have a plate structure. Alternatively, the upper electrode 280 may be conformally formed on the dielectric layer 275 along a profile of the lower electrode 270.

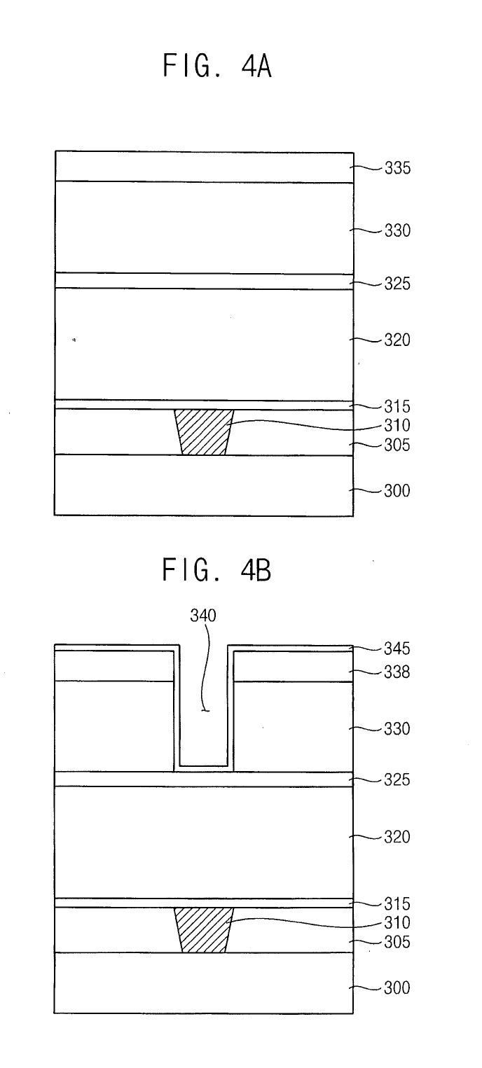

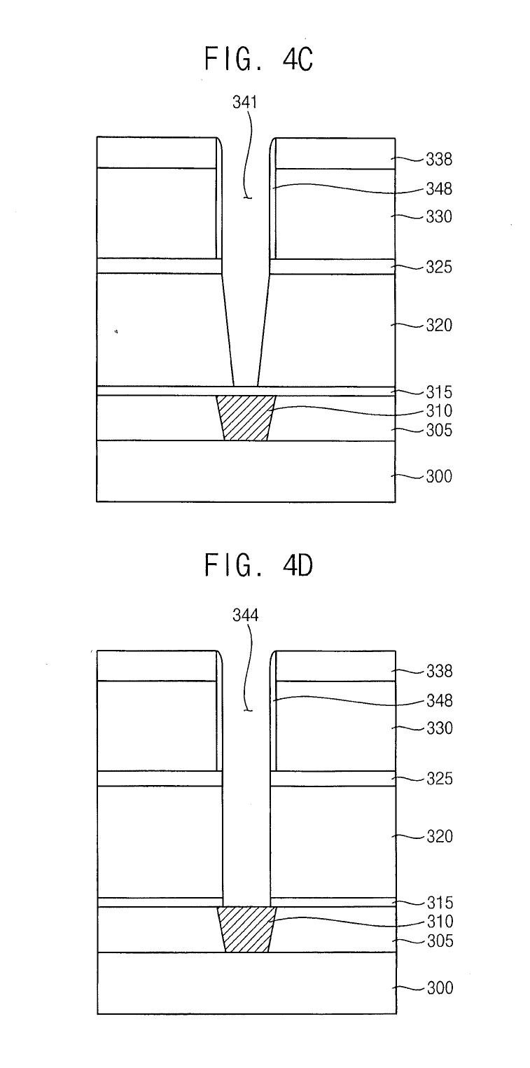

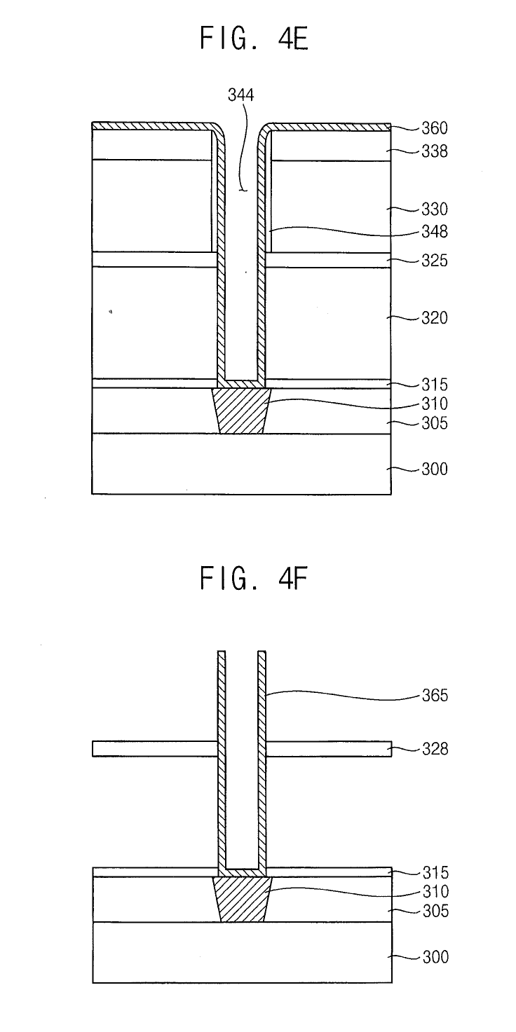

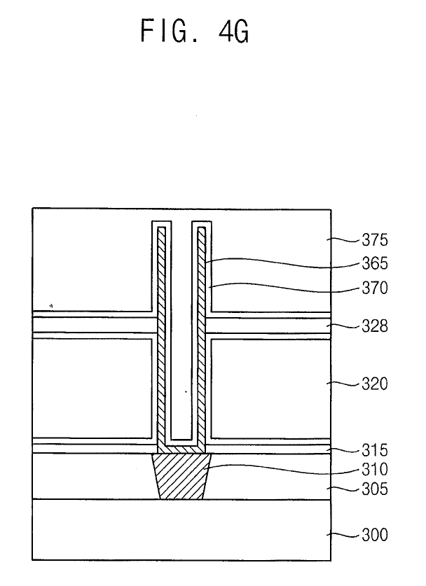

FIGS. 4A to 4G are cross-sections illustrating methods of manufacturing semiconductor devices in accordance with some embodiments of the present inventive concept. Referring to FIG. 4A, an insulation layer 305 having a pad 310 may be formed on a substrate 300 having a lower structure. The pad 310 may be electrically connected to the lower structure or a predetermined portion of the substrate 300. The lower structure may include switching devices such as transistors, diodes, etc. Further, the lower structure may have contact regions, plugs, pads, conductive patterns, insulation patterns, spacers, etc.

An etch stop layer 315 on the pad 310 and the insulation layer 305, and then a lower mold structure having a first mold layer 320 is formed on the etch stop layer 315. A supporting layer 325 and an upper mold structure having a second mold layer 330 may be successively formed on the etch stop layer 315. That is, the supporting layer 325 may be interposed between the lower mold structure and the upper mold structure. In example embodiments, each of the lower mold structure and the upper mold structure may have at least one additional mold layer. In this case, the at least one additional mold layer may include an oxide substantially same as or substantially similar to that of the first mold layer 320 and/or the second mold layer 330. Alternatively, the at least one additional mold layers may include an oxide substantially different from that of the first mold layer 320 and/or the second mold layer 330.

The supporting layer 325 may be formed using a nitride, and the first mold layer 320 and the second mold layer 330 may be formed using a first oxide and a second oxide, respectively. Here, the first oxide in the first mold layer 320 may be substantially different from the second oxide of the second mold layer 330. Alternatively, the first oxide of the first mold layer 320 may be substantially the same as or substantially similar to the second oxide in the second mold layer 330.

A mask layer 335 may be formed on the second mold layer 330. The mask layer 335 may be formed using a material having an etching selectivity with respect to the supporting layer 325, the first mold layer 320 and/or the second mold layer 330. For example, the mask layer 335 may include polysilicon, amorphous silicon, amorphous carbon, etc. Before forming the mask layer 335 on the second mold layer 330, an upper portion of the second mold layer 330 may be planarized.

Referring to FIG. 4B, the mask layer 335 may be patterned by a photolithography process to form a mask pattern 338 on the second mold layer 330. The mask pattern 338 may expose a portion of the second mold layer 330 located over the pad 310.

With a first etching process using the mask pattern 338 as an etching mask, the exposed portion of the second mold layer 330 may be etched to form a first opening 340 that exposes a portion of the supporting layer 325. Namely, the first opening 340 may be formed through the second mold layer 330 only.

In some embodiments, the second mold layer 330 may be additionally etched to enlarge a width of the first opening 340. When the second mold layer 330 includes oxide, the second mold layer 330 may be partially etched using an etching solution including hydrogen fluoride, so that the first opening 340 may have an enlarged width.

A spacer formation layer 345 may be formed on the exposed portion of the supporting layer 325, a sidewall of the first opening 340 and the mask pattern 338. The spacer formation layer 345 may be conformally formed along a profile of the first opening 340. For example, the spacer formation layer 345 may be formed using silicon oxide, silicon oxynitride, etc.

Referring to FIG. 4C, a spacer 348 may be formed on the sidewall of the first opening 340 by partially etching a portion of the spacer formation layer 345. For example, the spacer 348 may be obtained by anisotropically etching the spacer formation layer 345. In this case, a lower portion of the spacer 348 may make contact with the supporting layer 325.

A second etching process may be performed about the supporting layer 325 and the first mold layer 320 using the mask pattern 338 and the spacer 348 as etching masks. Thus, a second opening 341 may be formed through the second mold layer 330 to the first mold layer 320. That is, portions of the supporting layer 325 and the first mold layer 320 may be etched to form the second opening 341 that exposes the etch stop layer 315. In the second etching process, the second opening 314 may expose the etch stop layer 315 with a relatively small first area.

In some embodiments, the supporting layer 325 may be partially etched, and then the first mold layer 320 may be partially etched to provide the second opening 341 through the second mold layer 330, the supporting layer 325 and the first mold layer 320.

Referring to FIG. 4D, a third etching process may be executed on the etch stop layer 315 still using the mask pattern 338 and the spacer 348 as etching masks. In the third etching process, the etch stop layer 315 may be partially etched along a direction substantially perpendicular relative to the substrate 300. Hence, a third opening (not illustrated) exposing a portion of the pad 310 with a relatively small first area may be formed from the second mold layer 330 to the etch stop layer 315. The etch stop layer 315 may be partially etched using an etching solution or an etching gas including phosphoric acid or sulfuric acid.

A fourth etching process may be carried using the mask pattern 338 and the spacer 348 as etching masks. The etch stop layer 315 may be partially etched along a direction substantially parallel relative to the substrate 300 in the fourth etching process, so that a fourth opening (not illustrated) exposing a portion of the pad 310 with a relatively large second area may be obtained. In other words, a lower portion of the fourth opening may be enlarged from a lower portion of the third opening by the fourth etching process.

A portion of the first mold layer 320 corresponding to a lower portion of the fourth opening may be etched to form a fifth opening 344 from the second mold layer 330 to the etch stop layer 315. The fifth opening 344 may have an enlarged lower portion from the fourth opening. In example embodiments, the fifth opening 344 may have a sidewall substantially perpendicular with respect to the substrate 300. The fifth opening 344 may be obtained by etching the portion of the first mold layer 320 using an etching solution or an etching gas including hydrogen fluoride.

Referring to FIG. 4E, a lower electrode layer 360 may be formed on the pad 310, the sidewall of the fifth opening 344 and the mask pattern 338. The lower electrode layer 360 may be uniformly formed on the pad 310 along the sidewall of the fifth opening 344. The lower electrode layer 360 may be formed using a metal and/or a metal compound.

In some embodiments, after removing the spacer 348 from an upper sidewall of the fifth opening 344, the lower electrode layer 360 may be formed on the sidewall of the fifth opening 344. Since a width of an upper portion of the fifth opening 344 may be enlarged about more than two times of a width of the spacer 348, a width of an upper portion of the lower electrode 365 (see FIG. 4F) may be greatly enlarged. Additionally, a lateral portion of the lower electrode 365 may have a substantially perpendicular stepped structure relative to the substrate 300.

Referring to FIG. 4F, a portion of the lower electrode layer 360 and the mask pattern 338 may be removed to expose the second mold layer 330. Thus, the lower electrode 365 may be formed on the sidewall of the fifth opening 344 and the pad 310.

When the first mold layer 320 and the second mold layer 330 may be removed from the lower electrode 365, the supporting layer 325 may be changed into a supporting member 328 disposed between adjacent lower electrodes 365. The supporting member 328 may be connected to sidewalls of adjacent lower electrodes 365, so that the lower electrode 365 may not be collapsed, fallen down or leaned even though the lower electrode 365 has a high aspect ratio. Therefore, a capacitor including the lower electrode 365 and the supporting member 328 may ensure enhanced structural stability.

Referring to FIG. 4G, a dielectric layer 370 may be conformally formed on the lower electrode 365 and the supporting member 328, and an upper electrode 375 sufficiently covering the lower electrode 365 may be formed on the dielectric layer 370. Thus, the capacitor may contact the pad 310 with a relatively contact area. That is, the capacitor may have improved electrical connection between the pad 310 and the lower electrode 365. As described above, the upper electrode 375 may be uniformly formed on the dielectric layer 370.

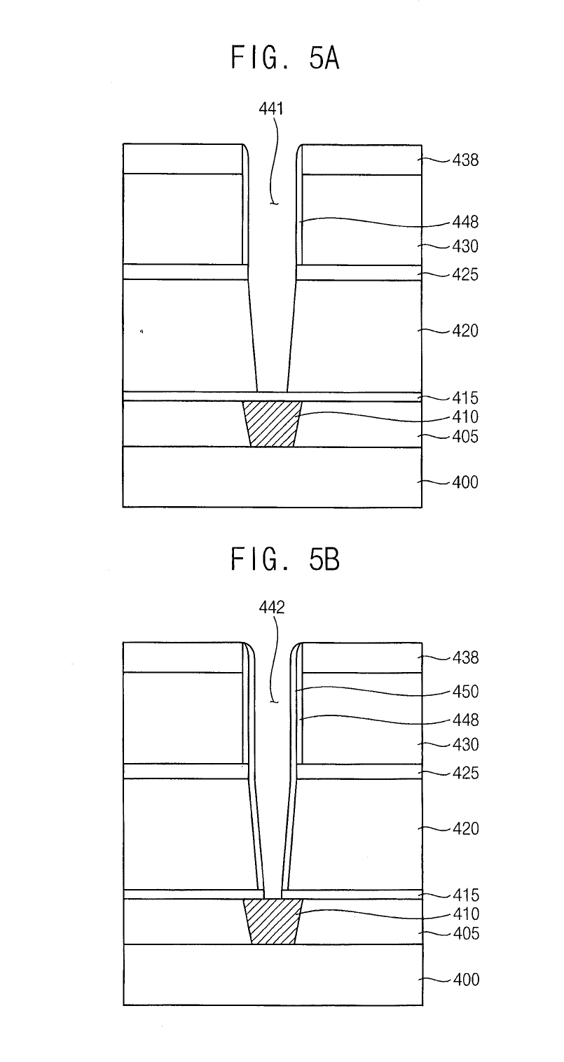

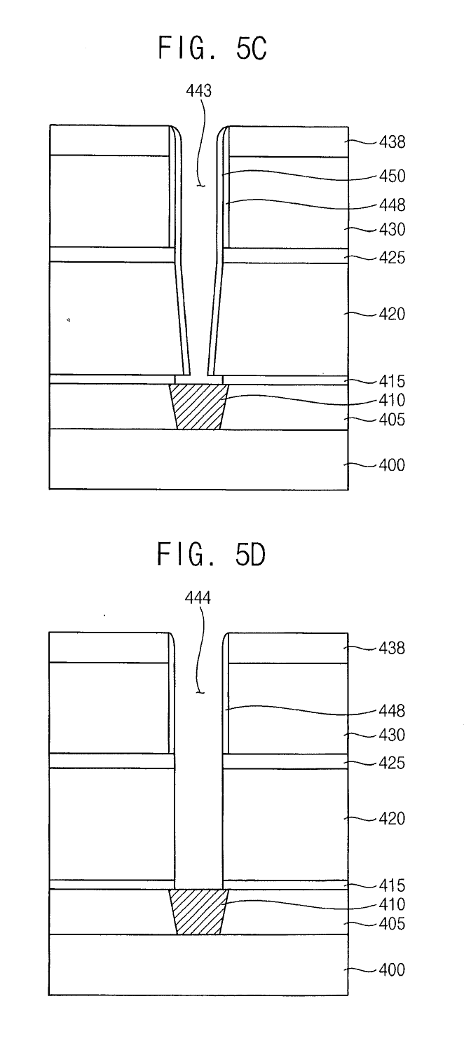

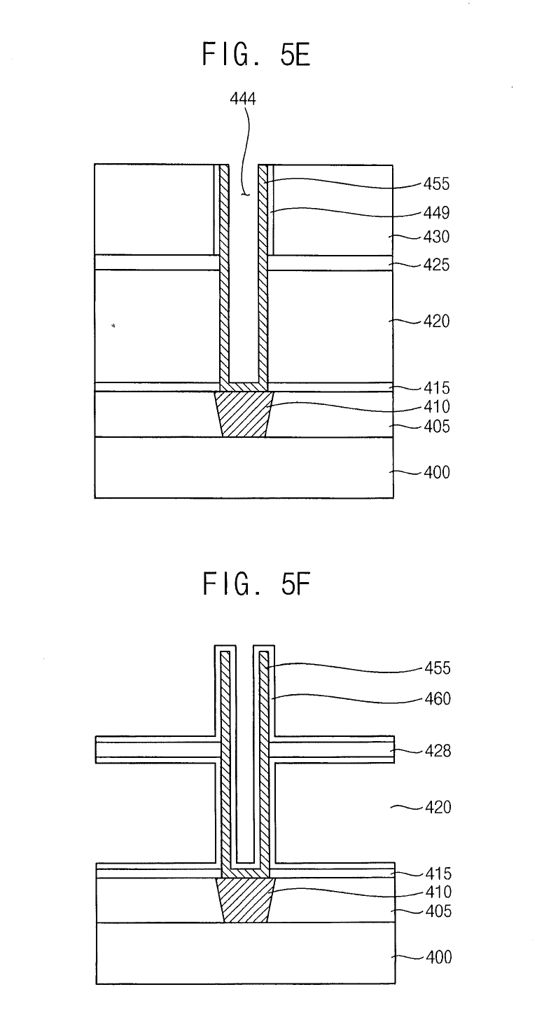

FIGS. 5A to 5F are cross-sections illustrating methods of manufacturing semiconductor devices in accordance with some embodiments of the present inventive concept. Referring to FIG. 5A, an insulation layer 405 may be formed on a substrate 400 and then a pad 410 may be formed on the substrate 400 through the insulation layer 405. In some example embodiments, the insulation layer 405 may have a level upper face by a planarization process, for example, a CMP process, an etch-back process, etc. The substrate 400 may have a lower structure that including switching devices, contact region, conductive patterns, spacers, pads, etc.

An etch stop layer 415 may be formed on the insulation layer 405 and the pad 410. The etch stop layer 415 may have a relatively small thickness. For example, the etch stop layer 415 may be formed using silicon nitride.

A lower mold structure, a supporting layer 425 and an upper mold structure may be successively formed on the etch stop layer 415. The lower mold structure may have a first mold layer 420 and the upper mold structure may include a second mold layer 430. In some example embodiments, each of the upper and the lower mold structures may include at least one additional mold layer.

A mask pattern 438 may be formed on the second mold layer 430. The mask pattern 438 may expose a portion of the second mold layer 430 where the pad 410 is disposed.

By a first etching process using the mask pattern 438 as an etching mask, the second mold layer 430 may be partially etched to form a first opening (not illustrated) that exposes a portion of the supporting layer 425. In some example embodiments, an additional process for enlarging a width of the first opening may be performed. For example, the first opening may be enlarged by a cleaning process using an LAL solution when the second mold layer 430 includes oxide.

A first spacer 448 may be formed on a sidewall of the first opening. For example, the first spacer 448 may be formed using silicon oxide or silicon oxynitride. Here, a lower portion of the first spacer 448 may be positioned on the supporting layer 425.

By a second etching process using the first spacer 448 and the mask pattern 438 as etching masks, the supporting layer 425 and the first mold layer 420 may be partially etched to form a second opening 441 from the second mold layer 430 to the first mold layer 420. The second opening 441 may expose a portion of the etch stop layer 425 with a relatively small area. In example embodiments, the second opening 441 may have an upper portion substantially perpendicular to the substrate 400, and a lower portion substantially inclined with respect to the substrate 400. That is, a lower sidewall of the second opening 441 may be substantially inclined relative to the substrate 400 whereas an upper sidewall of the second opening 441 may be substantially perpendicular to the substrate 400. Thus, the second opening 441 may have a lower width substantially smaller than an upper width thereof.

Referring to FIG. 5B, a second spacer 450 may be formed on the first spacer 448 and the lower sidewall of the second opening 441. The second spacer 450 may be formed using oxide or oxynitride. For example, the second spacer 450 may be formed using silicon oxide, silicon oxynitride, etc. A lower portion of the second spacer 450 may contact the exposed portion of the etch stop layer 415. In example embodiments, the second spacer 450 may include a material substantially the same as or substantially similar to that of the first spacer 448. Alternatively, the second spacer 450 may be formed using a material substantially different from that of the first spacer 448. However, all of the first spacer 448 and the second spacer 450 may be formed using materials having an etching selectivity relative to the etch stop layer 415 and/or the supporting layer 425.

With a third etching process using the second spacer 450 and the mask pattern 438 as etching masks, the etch stop layer 415 may be partially etched along a direction substantially perpendicular relative to the substrate 400. Hence, there is provided a third opening 442 that exposes a portion of the pad 410 with a relatively small area. Namely, the third opening 442 may be formed from the second mold layer 430 to the etch stop layer 415.

Referring to FIG. 5C, by a fourth etching process still using the second spacer 450 and the mask pattern 438 as etching masks, the etch stop layer 415 may be partially etched along a direction substantially parallel with respect to the substrate 400. Therefore, a fourth opening 443 may be formed from the third opening 442. The fourth opening 443 may have a lower portion enlarged from that of the third opening 442. The fourth opening 443 may expose a portion of the pad 410 with a relatively wide area. In this case, a width of the lower portion of the fourth opening 443 may be substantially the same as or substantially similar to a width of an upper portion of the pad 410. Alternatively, the width of the lower portion of the fourth opening 443 may be substantially larger than the width of the upper portion of the pad 410.

Referring to FIG. 5D, the first mold layer 420 may be exposed by removing the second spacer 450 from a sidewall of the fourth opening 443. The first mold layer 420 may be partially etched to form a fifth opening 444 enlarged from the fourth opening 443. The fifth opening 444 may have a lower width substantially larger than a lower width of the fourth opening 443. For example, the fifth opening 444 may have a lower sidewall and an upper sidewall substantially perpendicular relative to the substrate 400. As described above, a width of a lower portion of the fifth opening 444 may be substantially the same as or substantially similar to the width of the pad 410. However, the width of the lower portion of the fourth opening 443 may be substantially larger than the width of the pad 410.

Referring to FIG. 5E, a lower electrode layer (not illustrated) may be formed on the mask pattern 438, the sidewall of the fifth opening 444, the portion of the pad 410 exposed with the relatively large area. The lower electrode layer may be conformally formed along a profile of the fifth opening 444.

Portions of the lower electrode layer and the first spacer 448 may be removed until the second mold layer 430 is exposed. Thus, a lower electrode 455 may be formed on the pad 410 and the sidewall of the fifth opening 444 while forming a remaining first spacer 449 on an upper sidewall the lower electrode 455. That is, an upper portion of the first spacer 449 may be removed in forming the lower electrode 455, so that the remaining first spacer 449 may be obtained between the second mold layer 430 and the lower electrode 455.

In some embodiments, before forming the lower electrode layer, the first spacer 448 may be removed from the sidewall of the fifth opening 444. That is, the lower electrode layer may be formed after removing the first spacer. In this case, the lower electrode 455 may have a more enlarged upper width.

Referring to FIG. 5F, the second mold layer 430, the first mold layer 420 and the remaining first spacer 449 may be removed from the lower electrode 455. A supporting member 428 contacting an outer sidewall of the lower electrode 455 may be formed from the first supporting layer 425 after removing the second mold layer 430, the first mold layer 420 and the remaining first spacer 449. In example embodiments, the remaining first spacer 449, the first mold layer 420 and the second mold layer 430 may be simultaneously removed. Alternatively, the first mold layer 420 and the second mold layer 430 may be removed, and then the remaining first spacer 449 may be removed from the lower electrode 455.

A dielectric layer 460 may be uniformly formed on the lower electrode 455 and the supporting member 428, and an upper electrode (not illustrated) may be formed on the dielectric layer 460. Thus, a capacitor having the lower electrode 455, the dielectric layer 460 and the upper electrode may be formed over the substrate 400. The capacitor may be electrically connected to the lower structure and/or the substrate 400 through the pad 410.

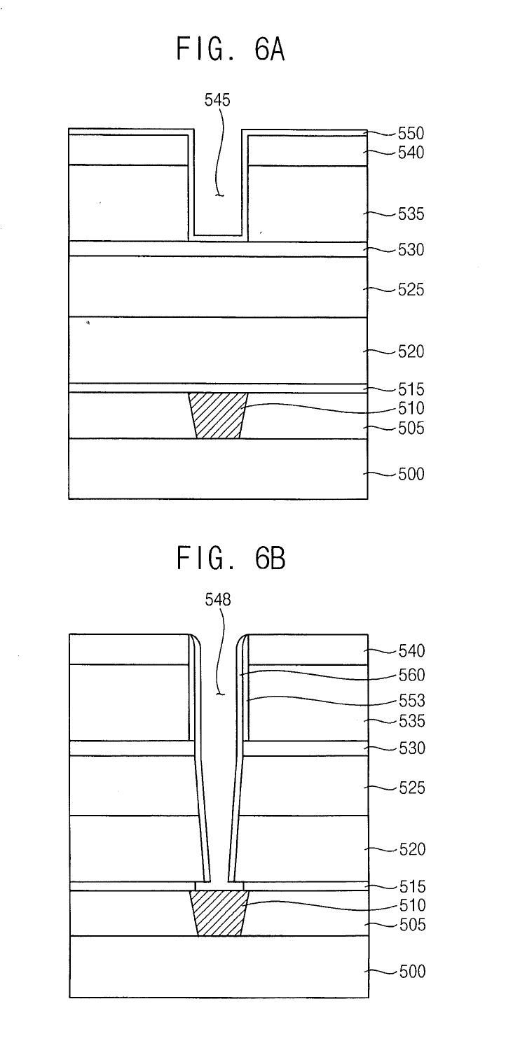

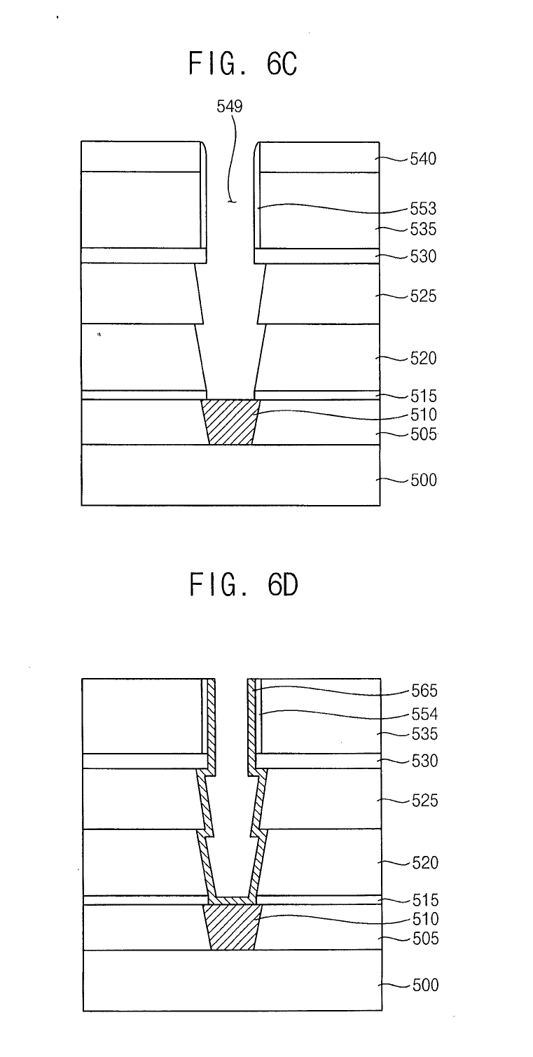

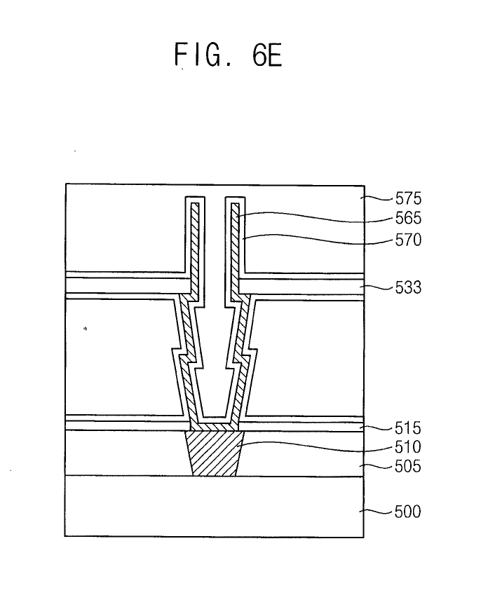

FIGS. 6A to 6E are cross-sections illustrating methods of manufacturing semiconductor devices in accordance with some embodiments of the present inventive concept. Referring to FIG. 6A, after forming an insulation layer 505 on a substrate 500, a pad 510 may be formed through the insulation layer 505. The pad 510 may be electrically connected to a lower structure provided on the substrate 500. When the semiconductor device includes a dynamic random access memory (DRAM) device, the lower structure may have a switching device such as a metal oxide semiconductor (MOS) transistor.

After forming an etch stop layer 515 on the insulation layer 505 having the pad 510, a lower mold structure including a first mold layer 520 and a second mold layer 525 may be formed on the etch stop layer 515. Here, the first mold layer 520 and the second mold layer 525 may be formed using substantially different oxides.

A supporting layer 530 and an upper mold structure including a third mold layer 535 may be formed on the second mold layer 525. In some example embodiment, the upper mold structure may additionally include at least one additional mold layer formed on the third mold layer 535. In this case, the additional mold layer may be formed using oxide substantially the same as or substantially similar to that of the third mold layer 535. Alternatively, the additional mold layer may include oxide substantially different from that of the third mold layer 535.

A mask pattern 540 may be formed on the third mold layer 535 of the upper mold structure using a material having an etching selectivity relative to the supporting layer 530, the upper mold structure and the lower mold structure.

A first etching process may be carried out about the third mold layer 535 using the mask pattern 540 as an etching mask, so that the third mold layer 535 may be partially etched to form a first opening 545 exposing the supporting layer 530. In some example embodiments, a width of the first opening 545 may be enlarged by an additional process, for example, a cleaning process.

A spacer formation layer 550 may be formed on the exposed supporting layer 530, a sidewall of the first opening 545 and the mask pattern 550. The first spacer formation layer 550 may be uniformly formed along a profile of the first opening 545. For example, the first spacer formation layer 550 may include silicon oxide or silicon oxynitride.

Referring to FIG. 6B, the first spacer formation layer 550 may be partially etched to form a first spacer 553 on the sidewall of the first opening 545. For example, the spacer 553 may be obtained by an anisotropic etching process. In this case, a lower portion of the first spacer 553 may make contact with the supporting layer 530.

By a second etching process using the spacer 553 and the mask pattern 540 as etching masks, the supporting layer 530, the second mold layer 525 and the first mold layer 520 may be partially etched. Hence, a second opening (not illustrated) may be formed to partially expose the etch stop layer 515. The second opening may be formed from the third mold layer 535 to the first mold layer 520. The second opening may expose a portion of the etch stop layer 515 with a relatively small area.

A second spacer formation layer (not illustrated) may be formed on a sidewall of the second opening, the exposed portion of the etch stop layer 515 and the mask pattern 540. For example, the second spacer formation layer may be formed using silicon oxide, silicon oxynitride, etc. The second spacer formation layer may be conformally formed along a profile of the second opening.

The second spacer formation layer may be partially etched to form a second spacer 560 on a sidewall of the second opening. The second spacer 560 may be formed by an anisotropic etching process.

By a third etching process using the mask pattern 540 and the second spacer 560 as etching masks, the etch stop layer 515 may be etched along a direction substantially perpendicular relative to the substrate 500. As a result, a third opening (not illustrated) exposing the pad 510 to a relatively small area may be formed. The third opening may be formed from the third mold layer 535 to the etch stop layer 515.

A fourth etching process may be performed about the etch stop layer 515 still using the second spacer 560 and the mask pattern 540 as etching masks. In the fifth etching process, the etch stop layer 515 may be partially etched along a direction substantially parallel relative to the substrate 500. As a result, a fourth opening 548 exposing a portion of the pad 510 may be formed from the third mold layer 535 to the etch stop layer 515. The fourth opening 548 may expose the portion of the pad 510 with a relatively large area.

Referring to FIG. 6C, the second spacer 560 may be removed from a lower sidewall of the fourth opening 548, and then the first mold layer 520 and the second mold layer 525 may be partially etched. Thus, a fifth opening 549 having a stepped structure may be obtained because of etching rate difference between the first and the second mold layers 520 and 525.

When the oxide in the first mold layer 520 is substantially different from the oxide in the second mold layer 525, an etching rate of the first mold layer 520 may be substantially different from an etching rate of the second mold layer 525. Because of these different etching rates of the first and the second mold layers 520 and 525, a sidewall of the fifth opening 549 may have a stepped structure. As a result, the fifth opening 549 may include a lower portion having a width substantially larger than a width of a lower portion of the fourth opening 548.

Referring to FIG. 6D, a lower electrode 565 may be formed on a sidewall of the fifth opening 549 and the pad 510. The lower electrode 565 may be conformally formed along a profile of the fifth opening 549. Hence, a lower portion of the lower electrode 565 may have at least one stepped structure in accordance with that of the fifth opening 549.

Because the mask pattern 540 and an upper portion of the first spacer 553 may be removed in forming the lower electrode 565, a remaining first spacer 554 may be provided on an upper sidewall of the lower electrode 565.

Referring to FIG. 6E, after forming a supporting member 533 from the supporting layer 530 by removing the third mold layer 535, the second mold layer 525 and the first mold layer 510 from the lower electrode 565, the remaining first spacer 554 may be removed from the lower electrode 565.

A dielectric layer 570 may be formed on the lower electrode 565 and the supporting member 533, and an upper electrode 575 may be formed on the dielectric layer 570. Hence, a capacitor contacting the pad 510 may be provided over the substrate 500. The capacitor may include the lower electrode 565, the dielectric layer 570 and the upper electrode 575.

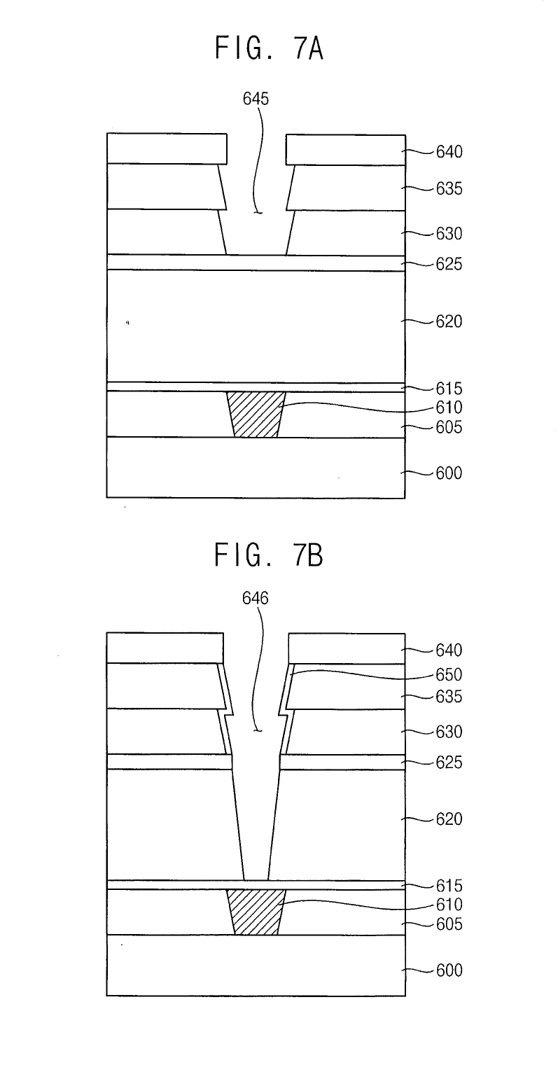

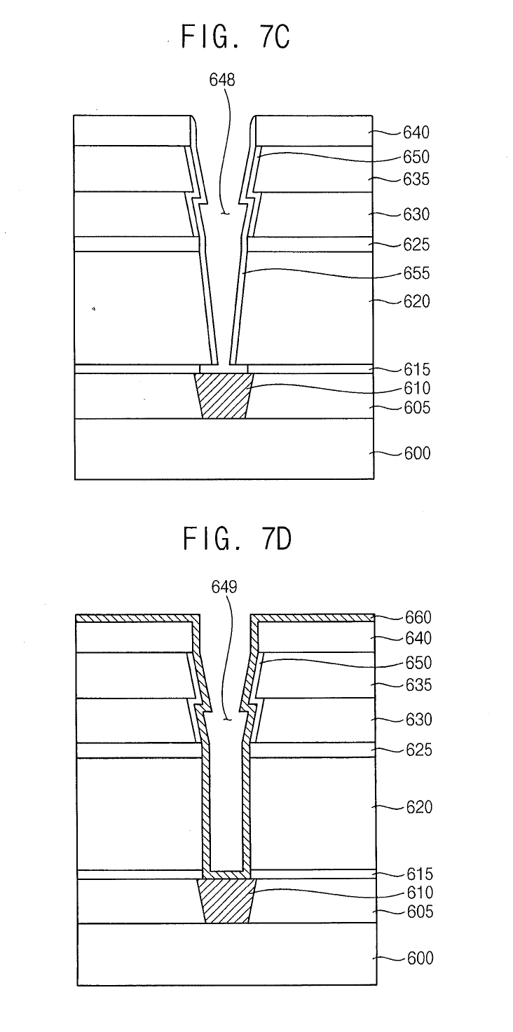

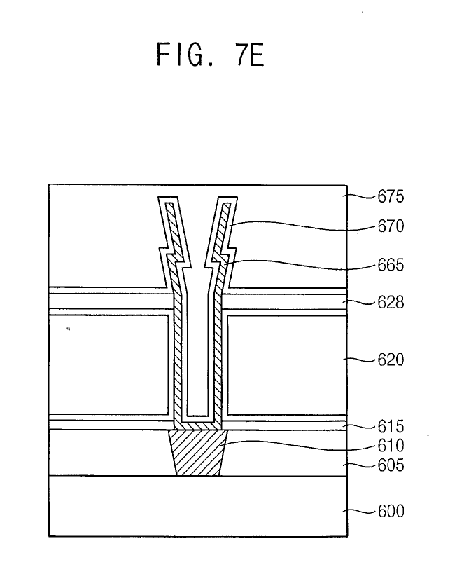

FIGS. 7A to 7E are cross-sections illustrating methods of manufacturing semiconductor devices in accordance with some embodiments of the present inventive concept. Referring to FIG. 7A, an insulation layer 605 and an etch stop layer 615 may be successively formed on a substrate 600. A pad 610 electrically contacting a lower structure may be formed on the substrate 600 through the insulation layer 605. Alternatively, the pad 610 may make contact with a contact region, a diffusion region, an impurity region or a conductive region formed on the substrate 600.

A lower mold structure including a first mold layer 620, a supporting layer 625 and an upper mold structure including a second mold layer 630 and a third mold layer 635 may be successively formed on the etch stop layer 615. In this case, the second mold layer 630 and the third mold layer 635 may include substantially different oxides. The lower mold structure may further include at least one additional mold layer disposed between the first mold layer 620 and the supporting layer 625. The additional mold layer may include a material substantially the same as or substantially similar to that of the first mold layer 620 or substantially different from that of the first mold layer 620.

A first etching process may be executed on the third and the second mold layers 635 and 630 using the mask pattern 640 as an etching mask after forming a mask pattern 640 on the third mold layer 635. In the first etching process, the third mold layer 635 and the second mold layer 630 may be successively to form a first opening 645 exposing the supporting layer 625. The first opening 645 may be formed from the third mold layer 635 to the second mold layer 630. When the third mold layer 635 and the second mold layer 630 have substantially different etching rates, a sidewall of the first opening 645 may have a stepped structure.

Referring to FIG. 7B, a first spacer 650 may be formed on the sidewall of the first opening 645. For example, the first spacer 650 may be formed using silicon oxide, silicon oxynitride, etc. The first spacer 650 may be uniformly formed along a profile of the first opening 645 having the stepped structure.

With a second etching process using the first spacer 650 and the mask pattern 640 as etching masks, the supporting layer 625 may be partially etched and then the first mold layer 620 may be partially etched. Thus, a second opening 646 exposing a portion of the etch stop layer 615 may be formed through from third mold layer 635 to the first mold layer 620. The second opening 646 may expose the portion of the etch stop layer 615 with a relatively small first area.

Referring to FIG. 7C, a second spacer 655 may be formed on a sidewall of the second opening 646. For example, the second spacer 655 may be formed using an oxide or an oxynitride.

A third etching process may be performed about the etch stop layer 615 using the second spacer 655 and the mask pattern 640 as etching masks. In the second etching process, the etch stop layer 615 may be partially etched along a direction substantially perpendicular relative to the substrate 600 to thereby form a third opening (not illustrated) that exposes a portion of the pad 610 with a relatively small first area. The third opening may be formed from the third mold layer 635 to the etch stop layer 615.

By a fourth etching process still using the second spacer 655 and the mask pattern 640 as etching masks, the etch stop layer 615 may be partially etched in a direction substantially parallel to the substrate 600. Hence, a fourth opening 648 is formed to expose a portion of the pad 610 with a relatively large second area. The fourth opening 648 may have a lower portion enlarged from a lower portion of the third opening. In example embodiments, the exposed portion of the pad 610 may be substantially equal to or substantially larger than a lower width of the fourth opening 648.

Referring to FIG. 7D, after removing the second spacer 655 from a sidewall of the fourth opening 648, a portion of the first mold layer 620 may be etched, so that a fifth opening 649 may be obtained. The fifth opening 649 may have an enlarged lower portion from the fourth opening 648. When the lower mold structure includes the additional mold layer besides the first mold layer 620, a lower sidewall of the fifth opening 649 may have at least one stepped portion.

A lower electrode layer 660 may be uniformly formed on the sidewall of the fifth opening 649, the pad 610 and the mask pattern 640. The lower electrode layer 660 may be formed using a metal and/or a metal compound. When a lower sidewall and an upper sidewall of the fifth opening 649 have stepped structures, a lower sidewall and an upper sidewall of the lower electrode layer 660 may have the stepped structures, respectively.

Referring to FIG. 7E, an upper portion of the lower electrode layer 660 and the mask pattern 640 are removed, so that a lower electrode 665 may be formed on the pad 610 and the sidewall of the fifth opening 649. For example, the lower electrode 665 may be obtained by a CMP process and/or an etch-back process. In example embodiments, at least one of an upper portion and a lower portion of the lower electrode 665 may have a stepped structure.

After removing the third mold layer 635, the second mold layer 630 and the first mold layer 620 from the lower electrode 665, the first spacer 650 may be removed from the lower electrode 665. Accordingly, a supporting member 628 may be obtained from the supporting layer 625. The supporting member 628 may be positioned between adjacent lower electrodes 665. For example, end portions of the supporting member 628 may make contact with upper portions of adjacent lower electrodes 665.

A dielectric layer 670 may be uniformly formed on the supporting member 628 and the lower electrode 665, and then an upper electrode 675 may be formed on the dielectric layer 670 to sufficiently cover the lower electrode 665. Therefore, a capacitor may be formed over the substrate 600. The capacitor having the lower electrode 665 may be electrically connected to a predetermined portion of the substrate 600 through the pad 610.

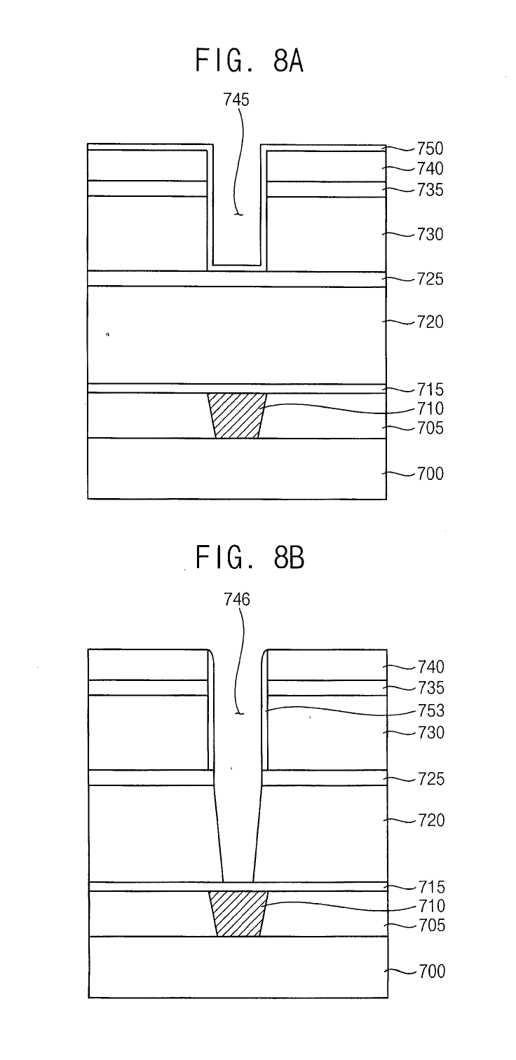

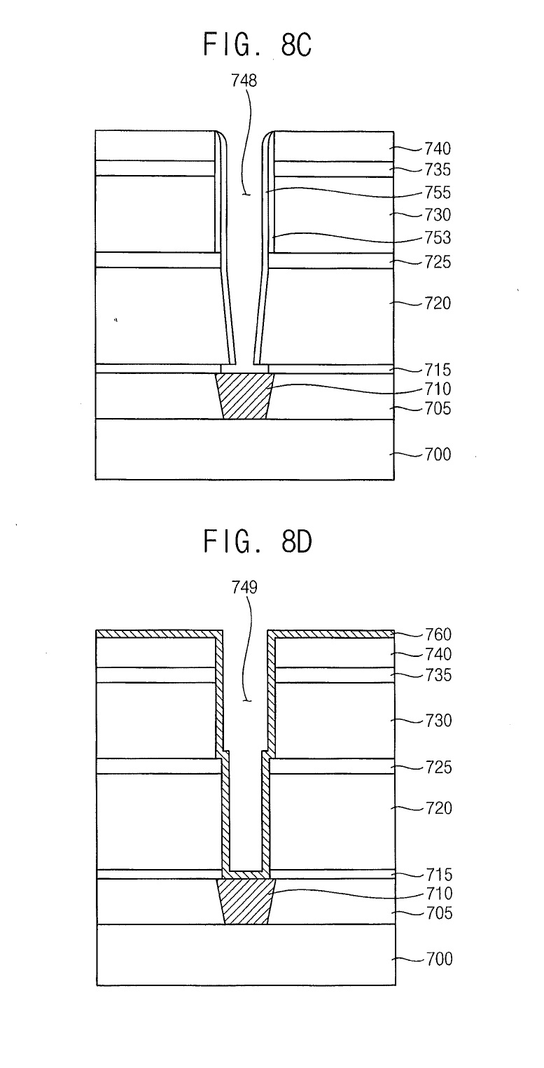

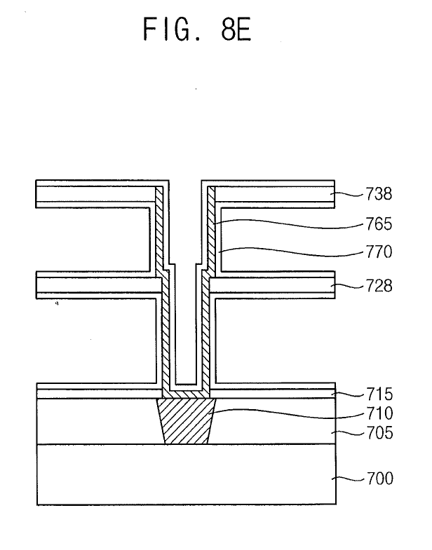

FIG. 8A to 8E are cross-sections illustrating methods of manufacturing semiconductor devices in accordance with some embodiments of the present inventive concept. Referring to FIG. 8A, an insulation layer 705 having a pad 710 may be formed on a substrate 700, and an etch stop layer 715 may be formed on the insulation layer 705 and the pad 710. The pad 710 may make contact with a predetermined region of the substrate 700 and/or a predetermined portion of a lower structure provided on the substrate 700.

A lower mold structure having a first mold layer 720, a first supporting layer 725, an upper mold structure having a second mold layer 730 and a second supporting layer 735 may be successively formed on the etch stop layer 715. For example, each of the first mold layer 720 and the second mold layer 735 may be formed using an oxide. Further, and each of the first supporting layer 725 and the second supporting layer 735may be formed using a nitride.

After forming a mask pattern 740 on the second supporting layer 735, a first etching process may be performed about the second supporting layer 735 and the second mold layer 730 using the mask pattern 740 as an etching mask. That is, the second supporting layer 735 and the second mold layer 730 may be partially etched to provide a first opening 745 that exposes a portion of the first supporting layer 725. The first opening 745 may be formed through the second supporting layer 735 and the second mold layer 730. The first opening 745 may have a sidewall substantially perpendicular to the substrate 700.

A first spacer formation layer 750 may be formed on the exposed portion of the first supporting layer 725, the sidewall of the first opening 745 and the mask pattern 740. The first spacer formation layer 750 may be formed using an oxide, an oxynitride and the like. For example, the first spacer formation layer 750 may include silicon oxide, silicon oxynitride, etc.

Referring to FIG. 8B, the first spacer formation layer 750 may be partially etched to provide a first spacer 753 on the sidewall of the first opening 745. Here, a lower portion of the first spacer 753 may be disposed on the first supporting layer 725. The first spacer 753 may be obtained by an anisotropic etching process.

The first supporting layer 725 and the first mold layer 720 may be partially etched by a second etching process using the first spacer 753 and the mask pattern 740 as etching masks. Thus, a second opening 746 exposing a portion of the etch stop layer 715 with a relatively small area may be formed through the second supporting layer 735, the second mold layer 730, the first supporting layer 725 and the first mold layer 720. The second opening 746 may have a lower portion substantially inclined relative to the substrate 700. That is, the second opening 746 may have a lower width substantially smaller than an upper width thereof.

Referring to FIG. 8C, a second spacer 755 may be formed on a sidewall of the second opening 746. The second spacer 755 may be formed using an oxide, an oxynitride, etc. An upper portion of the second spacer 755 may contact the first spacer 753, and a lower portion of the second spacer 755 may make contact with the first supporting layer 725 and the first mold layer 720. In example embodiments, the second spacer 755 may be obtained by anisotropically etching a second spacer formation layer (not illustrated) after forming the second spacer formation layer on the sidewall of the second opening 746 and the mask pattern 740.

A third etching process may be carried out about the exposed portion of the etch stop layer 715 using the second spacer 755 and the mask pattern 740 as etching masks. The etch stop layer 715 may be partially etched in a direction substantially perpendicular with respect to the substrate 700. Therefore, a third opening (not illustrated) may be formed to expose a portion of the pad 710 with a relatively small first area. The third opening may be formed from the second supporting layer 735 to the etch stop layer 715.

By a fourth etching process still using the second spacer 755 and the mask pattern 740 as etching masks, the etch stop layer 715 may be partially etched in a direction substantially parallel to the substrate 700. Thus, a fourth opening 748 may be formed to expose a portion of the pad 710 with a relatively large area.

Referring to FIG. 8D, after removing the second spacer 755 from the sidewall of the fourth opening 748, the first mold layer 720 may be partially etched to form a fifth opening 749 having a lower portion substantially wider than the lower portion of the fourth opening 548. That is, a lower width of the fifth opening 749 may be enlarged by partially etching the first mold layer 720.

The first spacer 753 may be removed from an upper sidewall of the fifth opening 749, and then a lower electrode layer 760 may be formed on a sidewall of the fifth opening 749, the pad 710 and the mask pattern 740. When the first spacer 753 is removed, the lower electrode layer 760 may have an upper portion substantially larger than a lower portion of the lower electrode layer 760.

Referring to FIG. 8E, a portion of the lower electrode layer 760 and the mask pattern 740 may be removed until the second supporting layer 735 is exposed. Hence, a lower electrode 765 may be formed on the pad 710 and the sidewall of the fifth opening 749. When the second mold layer 730 and the first mold layer 720 may be removed from the lower electrode 765, a first supporting member 728 and a second supporting member 738 may be formed from the first supporting layer 725 and the second supporting layer 735, respectively. The first and the second supporting members 728 and 738 may effectively support an upper portion and a central portion of the lower electrode 765. Namely, the first and the second supporting members 728 and 738 may be interposed among the upper portions and the central portions of adjacent lower electrodes 765, respectively.

After forming a dielectric layer 770 on the lower electrode 765, the first supporting member 728 and the second supporting member 738, an upper electrode (not illustrated) may be formed on the dielectric layer 770 to provide a capacitor over the substrate 700. The upper electrode may have a plate structure sufficiently covering the lower electrode 765. Alternatively, the upper electrode having a relatively thin thickness may be uniformly formed on the dielectric layer 770.

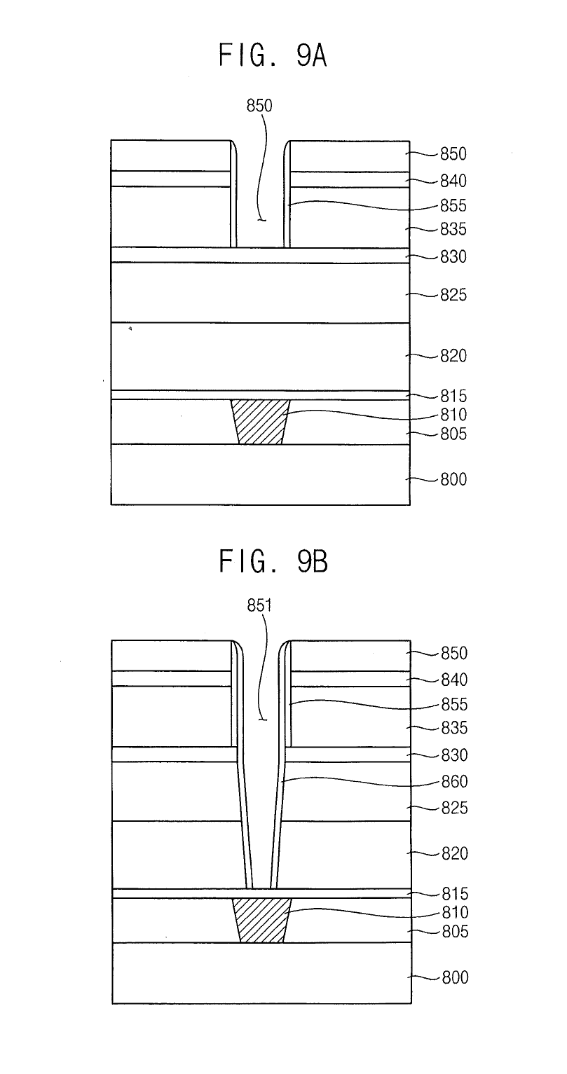

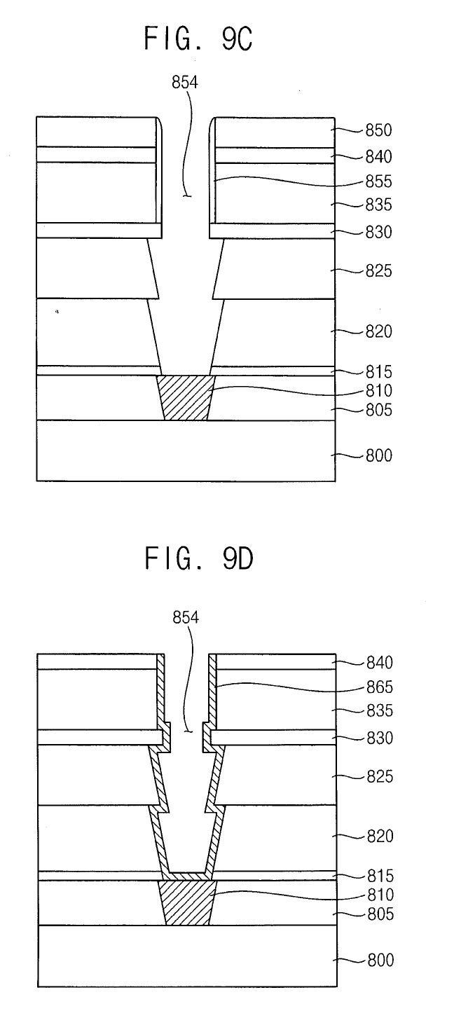

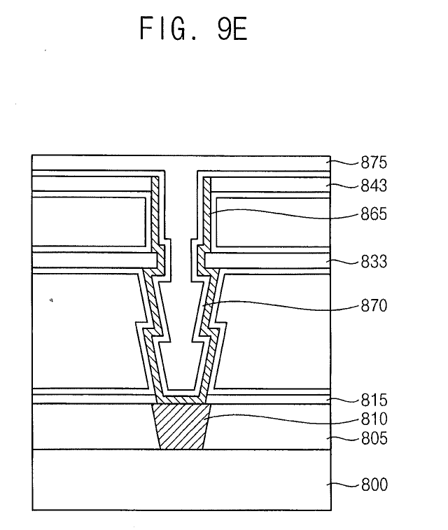

FIGS. 9A to 9E are cross-sections illustrating methods of manufacturing semiconductor devices in accordance with some embodiments of the present inventive concept.

Referring to FIG. 9A, an insulation layer 805 having a buried pad 810 may be formed on a substrate 800 having a lower structure thereon. The lower structure may include a switching device. The pad 810 may make contact with a predetermined portion of the substrate 800. For example, the pad 810 may contact a contact region, a conductive region, a diffusion region, an impurity region and the like.

An etch stop layer 815, a lower mold structure having a first mold layer 820 and a second mold layer 825, a first supporting layer 830, an upper mold structure having a third mold layer 835 and the second supporting layer 840 may be successively formed on the insulation layer 805 having the pad 810. The first mold layer 820 and the second mold layer 825 may include substantially different oxides. Additionally, the upper mold structure may have at least one additional mold layer disposed between the third mold layer 835 and the second supporting layer 840. Here, the additional mold layer may be formed using an oxide substantially different from that of the third mold layer 835.

After forming a mask pattern 845 on the second supporting layer 840, the second supporting layer 840 and the third mold layer 835 may be partially etched by a first etching process using the mask pattern 845 as an etching mask. Hence, a first opening 850 may be formed through the second supporting layer 840 and the third mold layer 835 to partially expose the first supporting layer 830. The first opening 850 may have a sidewall substantially perpendicular to the substrate 800.

A first spacer 855 may be formed on the sidewall of the first opening 850. The first spacer 855 may be formed using a material that has an etching selectivity with respect to the mask pattern 850, the first supporting layer 830 and/or the second supporting layer 840.

Referring to FIG. 9B, in a second etching process using the first spacer 855 and the mask pattern 845 as etching masks, the first supporting layer 830, the second mold layer 825 and the first mold layer 820 may be successively etched, such that a second opening 851 may be formed to expose a portion of the etch stop layer 815 with a relatively small first area. The second opening 851 may be formed through the second supporting layer 840 to the first mold layer 820. In example embodiments, an upper portion of the second opening 851 may have a width substantially larger than that of a lower portion of the second opening 851.

A second spacer 860 may be formed on a sidewall of the second opening 851. The second spacer 860 may be formed using an oxide or an oxynitride. In example embodiments, the first spacer 855 may include a material substantially the same as or substantially similar to that of the second spacer 860. Alternatively, the first and the second spacers 855 and 860 may include substantially different materials.

Referring to FIG. 9C, a third etching process may be executed on the exposed etch stop layer 715 using the second spacer 860 and the mask pattern 840 as etching masks. In the third etching process, the etch stop layer 815 may be partially etched in a direction substantially perpendicular to the substrate 800. Therefore, a third opening (not illustrated) exposing a portion of the pad 810 with a relatively small first area may be obtained. The third opening may be formed from the second supporting layer 840 to the etch stop layer 815.

By a fourth etching process still using the second spacer 860 and the mask pattern 840 as etching masks, the etch stop layer 815 may be partially along a direction substantially parallel to the substrate 800. Thus, a fourth opening (not illustrated) may be formed to expose the pad 810 with a relatively large second area. In this case, a lower width of the fourth opening may be substantially larger than an upper width of the third opening by partially etching the etch stop layer 715.

After forming the fourth opening, the second spacer 860 may be removed from a sidewall of the fourth opening. By etching portions of the first mold layer 820 and the second mold layer 825 after removing of the second spacer 860, a fifth opening 854 may be formed. The fifth opening 854 may have a lower width enlarged from that of the fourth opening. In example embodiments, the fifth opening 854 may have a lower sidewall having at least one stepped structure.

Referring to FIG. 9D, the first spacer 855 may be removed from an upper sidewall of the fifth opening 854, and then a lower electrode 865 may be formed on the sidewall of the fifth opening 854 and the pad 810. Thus, a lower portion of the lower electrode 865 may have an enlarged stepped structure. The mask pattern 845 may be removed from the second supporting layer 840 in a process of forming the lower electrode 865.

Referring to FIG. 9E, when the first to the third mold layers 820, 825 and 835 may be removed from the lower electrode 865, a first supporting member 833 and a second supporting 843 may be formed from the first supporting layer 830 and the second supporting layer, respectively. The first supporting member 833 and the second supporting member 843 may support an upper portion of the lower electrode 865 and a central portion of the lower electrode 865, respectively.

A dielectric layer 870 may be uniformly formed on the first supporting member 833, the second supporting member 843 and the lower electrode 865. An upper electrode 875 may be formed on the dielectric layer 870. As a result, a capacitor having the lower electrode 865, the dielectric layer 870 and the upper electrode 875 may be formed over the substrate 800. The capacitor may contact the pad 810 with improved connection stability.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the inventive concept. Accordingly, all such modifications are intended to be included within the scope of the inventive concept as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

1. A method of manufacturing a semiconductor device, comprising:
forming an insulation layer having a pad on a substrate;
forming an etch stop layer on the insulation layer and the pad;
forming a mold structure having at least one mold layer on the etch stop layer;
forming a first supporting layer on the mold structure;
etching the first supporting layer and the mold structure to form a first opening exposing the etch stop layer;
forming a spacer on a sidewall of the first opening;
etching the etch stop layer using the spacer as an etching mask to form a second opening exposing a portion of the pad having a first associated area;
etching the etch stop layer using the spacer as an etching mask to form a third opening exposing a second portion of the pad having a second associated area, the second associated area being larger than the first associated area; and
etching the mold structure to form a fourth opening having a width larger than a width of the third opening.

2. The method of claim 1, wherein forming the mold structure comprises:
forming a first mold layer on the etch stop layer; and
forming a second mold layer on the first mold layer.

3. The method of claim 2:
wherein the first mold layer and the second mold layer include different oxides;
wherein the first spacer includes an oxide or an oxynitride; and
wherein each of the etch stop layer and the first supporting layer includes a nitride.

4. The method of claim 1, further comprising:
forming a lower electrode on a sidewall of the fourth opening and the pad;
forming a first supporting member for supporting the lower electrode from the first supporting layer by removing the mold structure;
forming a dielectric layer on the lower electrode and the first supporting member; and
forming an upper electrode on the dielectric layer.

5. The method of claim 4, wherein the sidewall of the fourth opening has a stepped structure and a sidewall of the lower electrode has a stepped structure.

6. The method of claim 2, further comprising forming an upper mold structure on the first supporting layer, wherein the first opening defined by the upper mold structure to the first mold layer.

7. The method of claim 6, wherein forming the upper mold structure comprises forming a third mold layer on the first supporting layer.

8. The method of claim 7, wherein the third mold layer includes an oxide different from oxides of the first mold layer and the second mold layer.

9. The method of claim 7, further comprising:
forming a second supporting layer on the third mold layer; and
forming a second supporting member for supporting the lower electrode from the second supporting layer by removing the third mold layer with the first and the second mold layers.

10. The method of claim 1, wherein a sidewall of the fourth opening has a multi-stepped structure and a sidewall portion of the lower electrode has a multi-stepped structure.

11. A method of manufacturing a semiconductor device, comprising:
forming an insulation layer having a buried pad on a substrate;
forming an etch stop layer on the insulation layer and the pad;
forming a lower mold structure on the etch stop layer;
forming a first supporting layer on the lower mold structure;
forming an upper mold structure on the first supporting layer;
etching the upper mold structure to form a first opening exposing the first supporting layer;
forming a first spacer on a sidewall of the first opening;
etching the first supporting layer and the upper mold structure using the first spacer as an etching mask to form a second opening exposing the etch stop layer;
etching the etch stop layer in a direction substantially perpendicular to the substrate using the first spacer as an etching mask to form a third opening exposing the pad;
etching the etch stop layer in a direction substantially parallel to the substrate using the first spacer as an etching mask to form a fourth opening enlarging an exposed area of the pad; and
etching the lower mold structure to form a fifth opening having a lower width larger than a width of the fourth opening.

12. The method of claim 11, further comprising:
forming a lower electrode on a sidewall of the fifth opening and the pad;
forming a first supporting member for supporting the lower electrode from the first supporting layer by removing the upper mold structure and the lower mold structure; and
removing the first spacer.

13. The method of claim 11, further comprising:
forming a second spacer on a sidewall of the second opening; and
removing the second spacer after forming the fourth opening.

14. The method of claim 12:
wherein at least one of an upper sidewall and a lower sidewall of the fifth opening has a stepped structure; and
wherein at least one of an upper sidewall and a lower sidewall portion of the lower electrode has a stepped structure.

15. The method of claim 12, further comprising:
forming a second supporting layer on the upper mold structure; and
forming a second supporting member for supporting the lower electrode from the second supporting layer while removing the upper and the lower mold structures.

16.-18. (canceled)
